(19) United States
(12) Patent Application Publication
(10) Pub. No.: US 2014/0318601 A1
(43) Pub. Date: Oct. 30, 2014

(54) LIGHT GUIDE BODY, SOLAR CELL MODULE, AND SOLAR PHOTOVOLTAIC POWER GENERATION DEVICE

(71) Applicant: Sharp Kabushiki Kaisha, Osaka-shi, Osaka (JP)

(72) Inventors: Hideki Uchida, Osaka-shi (JP); Tokiyoshi Umeda, Osaka-shi (JP); Hideomi Yui, Osaka-shi (JP)

(21) Appl. No.: 14/358,231

(22) PCT Filed: Nov. 20, 2012
(86) PCT No.: PCT/JP2012/080079

§ 371 Date: May 15, 2014

(30) Foreign Application Priority Data
Nov. 24, 2011 (JP) 2011-256207

(51) Int. Cl. H01L 31/055; G02B 6/02; G02B 19/00

(52) U.S. Cl. CPC H01L 31/055; G02B 19/0076; G02B 6/02052
USPC 136/247; 385/129

(57) ABSTRACT

A light guide body includes a light-entering surface which outside light enters, one or more outside light-absorbing optical functional materials that absorb part of the outside light which enters the light-entering surface, a light-guiding optical functional material that is excited by energy of light absorbed by the one or more outside light-absorbing optical functional materials and that emits light different from the light, and a light-emitting surface whose area is smaller than the light-entering surface and from which the light emitted from the light-guiding optical functional material is emitted. A mixing ratio of the light-guiding optical functional material is smaller than a mixing ratio of at least an optical functional material having a largest mixing ratio among the one or more outside light-absorbing optical functional materials.

### TECHNICAL FIELD

The present invention relates to a light guide body, a solar cell module, and a solar photovoltaic power generation device.

This application claims priority based on Japanese Patent Application No. 2011-256207 filed in Japan on Nov. 24, 2011, the contents of which are hereby incorporated by reference herein.

### BACKGROUND ART

A solar photovoltaic power generation device described in PTL 1 is known as a solar photovoltaic power generation device in which solar cell elements are disposed on end surfaces of a light guide body and power generation is performed by causing light that propagates through the light guide body to enter the solar cell elements. The solar photovoltaic power generation device described in PTL 1 is configured to generate electric power by absorbing sunlight using fluorescence scattered in the light guide body and concentrating the fluorescence that propagates through the light guide body at the end surfaces of the light guide body.

In order to increase the power generation efficiency, PTL 2 proposes a structure in which a plurality of light guide bodies are stacked. Furthermore, in order to prevent the self-absorption of a fluorescent body caused when fluorescence is concentrated at end surfaces of a light guide body, NPL 1 proposes a method with which rubrene is added to the inside of a light guide body and the excitation energy of a fluorescent body is transferred by using near field energy transfer.

### CITATION LIST

### Patent Literature

PTL 1: Japanese Unexamined Patent Application Publication No. 58-49860
PTL 2: Japanese Unexamined Patent Application Publication No. 63-159812

### Non Patent Literature

NPL 1: SCIENCE Vol. 321, p. 226, JULY, 2008, “High-Efficiency Organic Solar Concentrators for Photovoltaics”, Michael J. Currie, et al.

### DISCLOSURE OF THE INVENTION

### Problems to be Solved by the Invention

In the above-described solar photovoltaic power generation device, sunlight used for exciting the fluorescent body is only part of sunlight that enters the light guide body. Most of sunlight that enters the light guide body is transmitted through the light guide body and does not contribute to power generation. Thus, a solar photovoltaic power generation device with high power generation efficiency cannot be provided.

It is an object of the present invention to provide a light guide body that absorbs outside light with high efficiency and can concentrate light at a light-emitting surface, a solar cell module that includes the light guide body and exhibits high power generation efficiency, and a solar photovoltaic power generation device including the solar cell module.

### Means for Solving the Problems

A light guide body according to an aspect of the present invention includes a light-entering surface which outside light enters, one or more outside light-absorbing optical functional materials that absorb part of the outside light which enters the light-entering surface, a light-guiding optical functional material that is excited by energy of light absorbed by the one or more outside light-absorbing optical functional materials and that emits light different from the light, and a light-emitting surface whose area is smaller than the light-entering surface and from which the light emitted from the light-guiding optical functional material is emitted. A mixing ratio of the light-guiding optical functional material is smaller than a mixing ratio of at least an optical functional material having a largest mixing ratio among the one or more outside light-absorbing optical functional materials.

The mixing ratio of the light-guiding optical functional material may be smaller than a mixing ratio of any of the one or more outside light-absorbing optical functional materials.

The mixing ratio of the light-guiding optical functional material may be 10% or less of the mixing ratio of the optical functional material having the largest mixing ratio among the one or more outside light-absorbing optical functional materials.

The one or more outside light-absorbing optical functional materials may include one or more optical functional materials having a fluorescence quantum yield of 80% or less.

A fluorescence quantum yield of the light-guiding optical functional material may be larger than a fluorescence quantum yield of at least an optical functional material having a smallest fluorescence quantum yield among the one or more outside light-absorbing optical functional materials.

The fluorescence quantum yield of the light-guiding optical functional material may be larger than a fluorescence quantum yield of any of the one or more outside light-absorbing optical functional materials.

At least one of types and mixing ratios of the one or more outside light-absorbing optical functional materials contained may be different between a portion close to the light-emitting surface and a portion farther from the light-emitting surface.

A spectrum of light emitted from the light-emitting surface may be different from a spectrum of light emitted from the light-entering surface.

Only one optical functional material may be used as the outside light-absorbing optical functional materials.

A plurality of optical functional materials may be used as the outside light-absorbing optical functional materials.

All light in a visible region may be absorbed by the plurality of outside light-absorbing optical functional materials, and light emitted from the light-guiding optical functional material may be infrared light.

A solar cell module according to another aspect of the present invention includes the light guide body of the present invention and a solar cell element that receives light emitted from the light-emitting surface of the light guide body. A spectral sensitivity of the solar cell element at a peak wavelength of an emission spectrum of the light-guiding optical functional material included in the light guide body is larger than a spectral sensitivity of the solar cell element at a peak wavelength of an emission spectrum of any of the one or more outside light-absorbing optical functional materials included in the light guide body.

The light-entering surface of the light guide body may be a flat surface.

The light guide body may be a plate-shaped flat member, and the solar cell element may receive the light which is emitted from an end surface of the light guide body, the end surface serving as the light-emitting surface.

At least part of the light-entering surface of the light guide body may be a bent surface or a curved surface.

The light guide body may be a plate-shaped curved member, and the solar cell element may receive the light which is emitted from a curved end surface of the light guide body, the curved end surface serving as the light-emitting surface.

The light guide body may be a cylindrical member, and the solar cell element may receive the light which is emitted from an end surface of the light guide body, the end surface serving as the light-emitting surface.

The light guide body may be a pillar-shaped member, and the solar cell element may receive the light which is emitted from an end surface of the light guide body, the end surface serving as the light-emitting surface.

A plurality of unitary units each including a pair of the light guide body and the solar cell element may be arranged so as to be adjacent to each other, and the plurality of unitary units may be flexibly connected to each other using a cord-shaped connecting member.

A plurality of unitary units each including a pair of the light guide body and the solar cell element may be arranged so as to be adjacent to each other, and the plurality of unitary units may be connected to each other so as to be separated from each other.

A solar photovoltaic power generation device according to another aspect of the present invention includes the solar cell module of the present invention.

### Effects of the Invention

According to aspects of the present invention, there can be provided a light guide body that absorbs outside light with high efficiency and can concentrate light at a light-emitting surface, a solar cell module that includes the light guide body and exhibits high power generation efficiency, and a solar photovoltaic power generation device including the solar cell module.

### BRIEF DESCRIPTION OF THE DRAWINGS

FIG. 1 is a schematic perspective view showing a solar cell module according to a first embodiment.

FIG. 2 is a sectional view showing the solar cell module.

FIG. 3 shows the absorption characteristics of outside light-absorbing optical functional materials.

FIG. 4 shows the absorption characteristics of outside light-absorbing optical functional materials.

FIG. 5 shows the emission characteristics of outside light-absorbing optical functional materials.

FIG. 6 shows the emission characteristics of outside light-absorbing optical functional materials.

FIG. 7 shows the emission characteristics and absorption characteristics of a light-guiding optical functional material together with the emission characteristics of an outside light-absorbing optical functional material.

FIG. 8 shows the emission characteristics and absorption characteristics of a system in which outside light-absorbing optical functional materials and a light-guiding optical functional material are mixed with each other.

FIG. 9A is a diagram for describing a Förster mechanism.

FIG. 9B is a diagram for describing a Förster mechanism.

FIG. 10A is a diagram for describing a Förster mechanism.

FIG. 10B is a diagram for describing a Förster mechanism.

FIG. 11 shows a relationship between the size of a light guide body and light output efficiency from an end surface of the light guide body.

FIG. 12 shows the energy conversion efficiency of various solar cells.

FIG. 13 shows the absorption characteristics of outside light-absorbing optical functional materials used in a solar cell module according to a second embodiment.

FIG. 14 shows a spectrum of sunlight after the sunlight passes through the light guide body.

FIG. 15 shows the emission characteristics and absorption characteristics of a light-guiding optical functional material together with the emission characteristics of an outside light-absorbing optical functional material.

FIG. 16 shows the emission characteristics and absorption characteristics of a system in which an outside light-absorbing optical functional material and a light-guiding optical functional material are mixed.

FIG. 17 is a plan view showing a light guide body that is applied to a solar cell module according to a fifth embodiment, the light guide body being viewed in a direction of the normal to a light-entering surface.

FIG. 18 is a schematic view showing a solar cell module according to a sixth embodiment.

FIG. 19 is a schematic view showing a solar cell module according to a seventh embodiment.

FIG. 20 is a schematic view showing a solar cell module according to an eighth embodiment.

FIG. 21 schematically shows a solar photovoltaic power generation device.

### BEST MODE FOR CARRYING OUT THE INVENTION

### First Embodiment

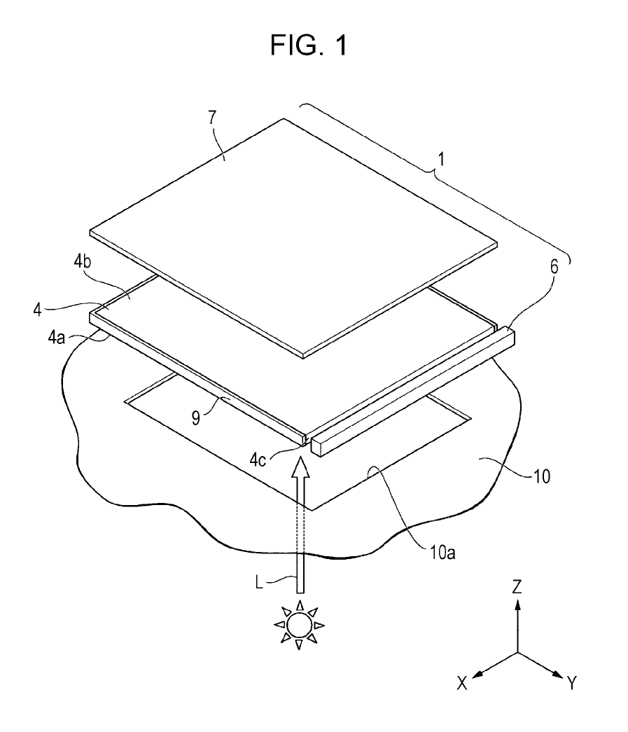

FIG. 1 is a schematic perspective view showing a solar cell module 1 according to a first embodiment.

The solar cell module 1 includes a light guide body 4 (fluorescence guide body), a solar cell element 6 that receives light emitted from a first end surface 4c of the light guide body 4, and a frame 10 that integrally supports the light guide body 4 and the solar cell element 6.

The light guide body 4 includes a first principal surface 4a serving as a light-entering surface, a second principal surface 4b that faces the first principal surface 4a, and the first end surface 4c serving as a light-emitting surface.

The light guide body 4 is a substantially rectangular plate-shaped member including the first principal surface 4a and the second principal surface 4b which are perpendicular to a Z axis (parallel to an XY plane). The light guide body 4 is obtained by dispersing a plurality of optical functional materials in a substrate (transparent substrate) composed of a highly transparent organic or inorganic material such as acrylic resin, polycarbonate resin, or glass. Examples of the optical functional materials include fluorescent bodies that absorb ultraviolet light or visible light and emit visible light or infrared light and nonluminous bodies that are excited through absorption of ultraviolet light or visible light but deactivate without emitting light. At least one optical functional material among the plurality of optical functional materials is a fluorescent body. Light emitted from the fluorescent body propagates through the light guide body 4 and is emitted from the first end surface 4c. The emitted light is used for power generation in the solar cell element 6.

The visible light is light in a wavelength range of 380 nm or more and 750 nm or less. The ultraviolet light is light in a wavelength range of less than 380 nm. The infrared light is light in a wavelength range of more than 750 nm.

In order for outside light to effectively enter the light guide body 4, the substrate (transparent substrate) of the light guide body 4 is desirably composed of a material having transparency to light with a wavelength of 400 nm or less. For example, the substrate is preferably composed of a material having a transmittance of 90% or more and more preferably composed of a material having a transmittance of 93% or more for light in a wavelength range of 360 nm or more and 800 nm or less. For example, a silicon resin substrate, a quartz substrate, and a PMMA resin substrate such as “Acrylite” (registered trademark) manufactured by MITSUBISHI RAYON CO., LTD. are suitably used because they have high transparency to light in a wide wavelength range.

The first principal surface 4a and the second principal surface 4b of the light guide body 4 are flat surfaces that are substantially parallel to the XY plane. A reflective layer 9 for reflecting, toward the inside of the light guide body 4, light (light emitted from the fluorescent body) that travels from the inside of the light guide body 4 toward the outside of the light guide body 4 is disposed on each of end surfaces of the light guide body 4 other than the first end surface 4c with an air layer therebetween or directly disposed on each of end surfaces of the light guide body 4 other than the first end surface 4c without an air layer therebetween. A reflective layer 7 for reflecting, toward the inside of the light guide body 4, light (light emitted from the fluorescent body) that travels from the inside of the light guide body 4 toward the outside of the light guide body 4 or light that enters the light guide body 4 through the first principal surface 4a but is not absorbed into the optical functional materials and is emitted from the second principal surface 4b is disposed on the second principal surface 4b of the light guide body 4 with an air layer therebetween or directly disposed on the second principal surface 4b of the light guide body 4 without an air layer therebetween.

Examples of the reflective layer 7 and the reflective layer 9 that can be used include reflective layers composed of a metal film made of silver, aluminum, or the like and reflective layers composed of a dielectric multilayer film such as an ESR (enhanced specular reflector) reflective film (manufactured by Sumitomo 3M Limited). The reflective layer 7 and the reflective layer 9 may be a specular reflective layer at which incident light is subjected to specular reflection or a diffuse reflective layer at which incident light is subjected to diffuse reflection. When the reflective layer 7 is a diffuse reflective layer, the amount of light that directly travels toward the solar cell element 6 increases and thus the efficiency of concentrating light at the solar cell element 6 increases, which increases the amount of power generation. Furthermore, since the reflected light is diffused, fluctuation in the amount of power generation due to time and season is averaged. An example of the diffuse reflective layer that can be used is a microcellular foamed PET (polyethylene terephthalate) (manufactured by Furukawa Electric Co., Ltd.).

The solar cell element 6 is disposed so that a light-receiving surface of the solar cell element 6 faces the first end surface 4c of the light guide body 4. The solar cell element 6 is preferably optically bonded to the first end surface 4c. A publicly known solar cell such as a silicon solar cell, a compound solar cell, or an organic solar cell can be used as the solar cell element 6. In particular, a compound solar cell that uses a compound semiconductor is suitably used as the solar cell element 6 because highly efficient power generation can be achieved.

FIG. 1 shows an example in which the solar cell element 6 is disposed on only one end surface of the light guide body 4, but the solar cell element 6 may be disposed on a plurality of end surfaces of the light guide body 4. When the solar cell element 6 is disposed on one or some of the end surfaces (one side, two sides, or three sides) of the light guide body 4, the reflective layer 9 is preferably disposed on an end surface or end surfaces on which the solar cell element is not disposed.

The frame 10 includes a transmissive surface 10a that transmits light L and is disposed so as to face the first principal surface 4a of the light guide body 4. The transmissive surface 10a may be an opening of the frame 10 or a transparent member composed of glass or the like and fitted in an opening of the frame 10. A portion of the first principal surface 4a of the light guide body 4 that overlaps the transmissive surface 10a of the frame 10 in a Z direction is a light-entering surface of the light guide body 4. The first end surface 4c of the light guide body 4 is a light-emitting surface of the light guide body 4.

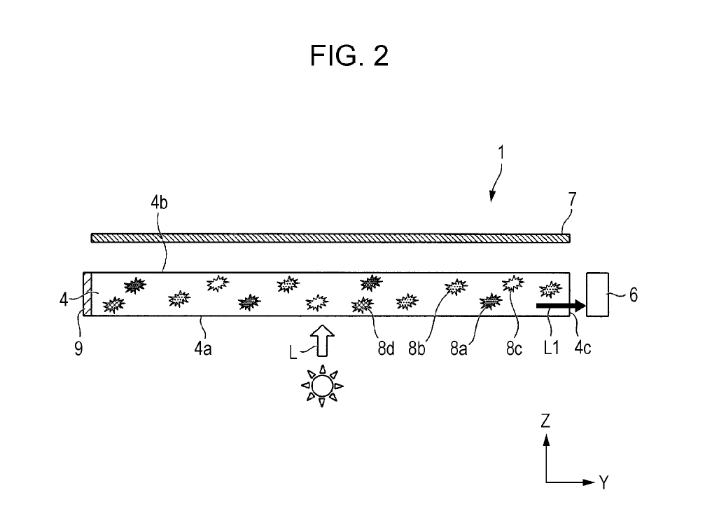

FIG. 2 is a sectional view showing a solar cell module 1.

In this embodiment, a plurality of types of fluorescent bodies (e.g., first fluorescent body 8a, second fluorescent body 8b, third fluorescent body 8c, and fourth fluorescent body 8d in FIG. 2) having different absorption wavelength ranges are dispersed as the optical functional materials in the light guide body 4. The first fluorescent body 8a absorbs ultraviolet light and emits blue fluorescence. The second fluorescent body 8b absorbs blue light and emits green fluorescence. The third fluorescent body 8c absorbs green light and emits orange fluorescence. The fourth fluorescent body 8d absorbs orange light and emits red fluorescence. The first fluorescent body 8a, the second fluorescent body 8b, the third fluorescent body 8c, and the fourth fluorescent body 8d are added, for example, when a PMMA resin is molded. The mixing ratios of the first fluorescent body 8a, the second fluorescent body 8b, the third fluorescent body 8c, and the fourth fluorescent body 8d are as follows. Note that the mixing ratios of the first fluorescent body 8a, the second fluorescent body 8b, the third fluorescent body 8c, and the fourth fluorescent body 8d are each expressed as a volume ratio relative to the PMMA resin included in the light guide body 4.

First fluorescent body 8a: (Blue) Lumogen 078 (trade name) manufactured by BASF 0.1%

Second fluorescent body 8b: (Green) Lumogen (trade name) manufactured by BASF 0.1%

Third fluorescent body 8c: (Orange) Lumogen (trade name) manufactured by BASF 0.2%

Fourth fluorescent body 8d: (Red) Lumogen (trade name) manufactured by BASF 0.005%

The mixing ratio (content in the light guide body 4) of the fourth fluorescent body 8d having the longest peak wavelength of an emission spectrum among the plurality of types of fluorescent bodies contained in the light guide body 4 is much smaller than those of other fluorescent bodies (first fluorescent body 8a, second fluorescent body 8b, and third fluorescent body 8c). In the light guide body 4, the first fluorescent body 8a, the second fluorescent body 8b, and the third fluorescent body 8c serve as outside light-absorbing optical functional materials and the fourth fluorescent body 8d serves as a light-guiding optical functional material that emits fluorescence as a result of energy transfer from the first fluorescent body 8a, the second fluorescent body 8b, and the third fluorescent body 8c through a Förster mechanism. The fourth fluorescent body 8d also absorbs outside light. However, since the mixing ratio of the fourth fluorescent body 8d is extremely small, the contribution to absorption of outside light is smaller than those of the first fluorescent body 8a, the second fluorescent body 8b, and the third fluorescent body 8c and thus the fourth fluorescent body 8d substantially does not function as an outside light-absorbing optical functional material. In the light guide body 4, functions are separated by employing the outside light-absorbing optical functional materials and the light-guiding functional material and the mixing ratio of the light-guiding optical functional material is decreased to be as small as possible, whereby the self-absorption caused by the light-guiding optical functional material during light guiding is suppressed.

The mixing ratio of the light-guiding optical functional material is smaller than the mixing ratio of at least an optical functional material mixed at the largest mixing ratio among the outside light-absorbing optical functional materials. In this embodiment, the mixing ratio of the light-guiding optical functional material is smaller than the mixing ratio of any of the outside light-absorbing optical functional materials.

The “outside light-absorbing optical functional material” refers to a luminous or nonluminous optical functional material that absorbs part of light that has entered the light guide body 4 through the light-entering surface 4a and makes a contribution to power generation. The outside light-absorbing optical functional material is mixed into the light guide body 4 at a large mixing ratio in order to achieve sufficient absorption of outside light. For example, the mixing ratio is more than 0.02%. The “light-guiding optical functional material” refers to an optical functional material (e.g., an optical functional material that is excited by absorbing fluorescence emitted from the outside light-absorbing optical functional material, converts the excitation energy into fluorescence, and emits the fluorescence; and an optical functional material that is excited as a result of energy transfer from the outside light-absorbing optical functional material through a Förster function, converts the excitation energy into fluorescence, and emits the fluorescence) that is excited by energy of light absorbed by the outside light-absorbing optical functional material and emits light different from the absorbed light. The light-guiding optical functional material substantially does not have a function of increasing the amount of power generation through absorption of outside light like the outside light-absorbing optical functional material. The light-guiding optical functional material is mixed into the light guide body 4 at an extremely small mixing ratio in order to suppress the self-absorption during light guiding. For example, the mixing ratio is 0.02% or less.

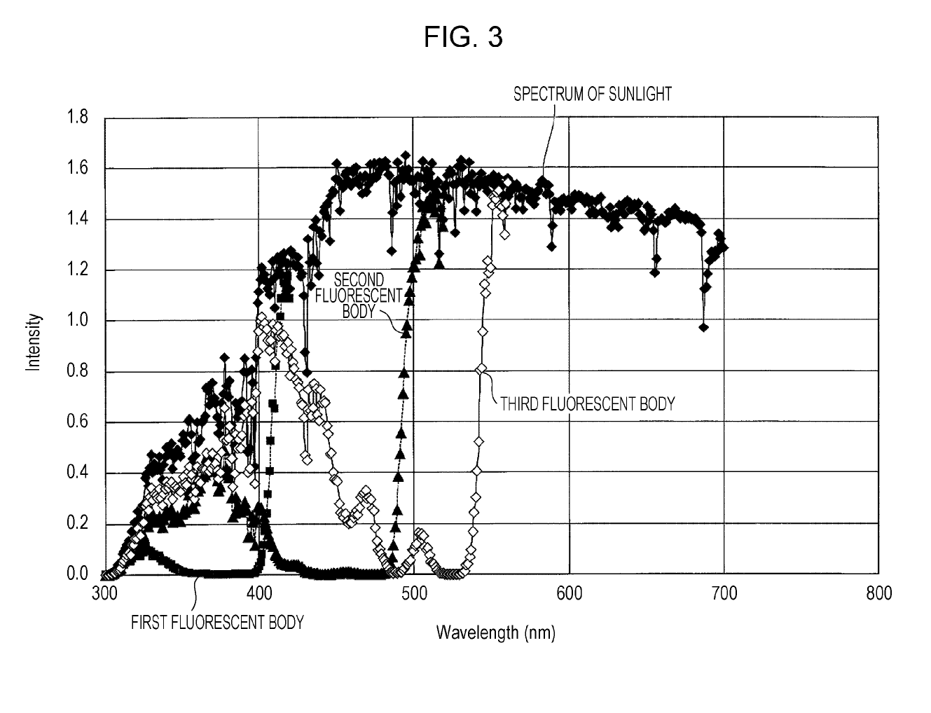

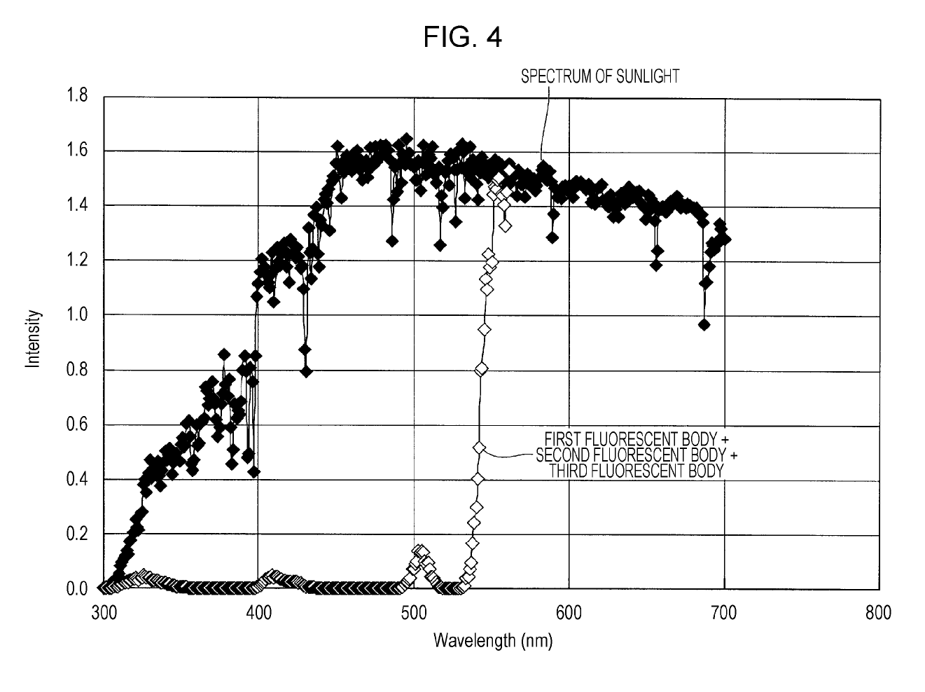

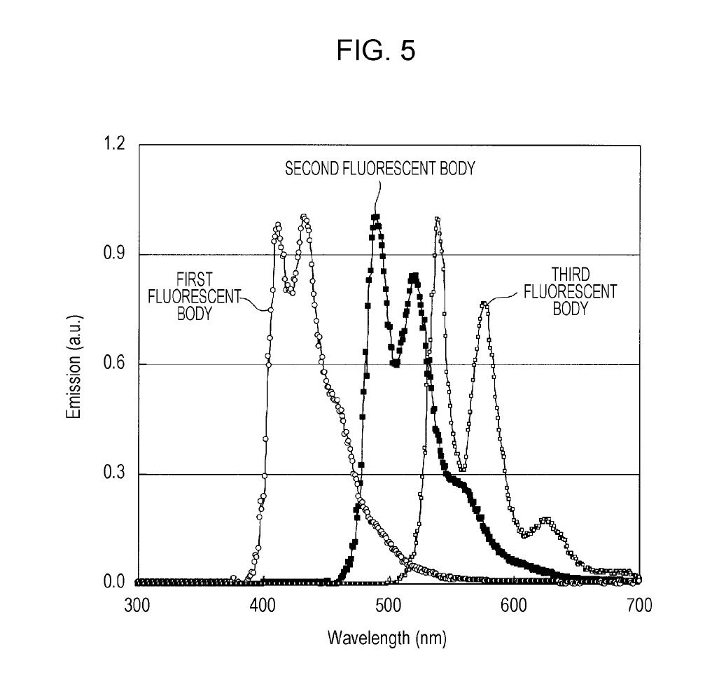

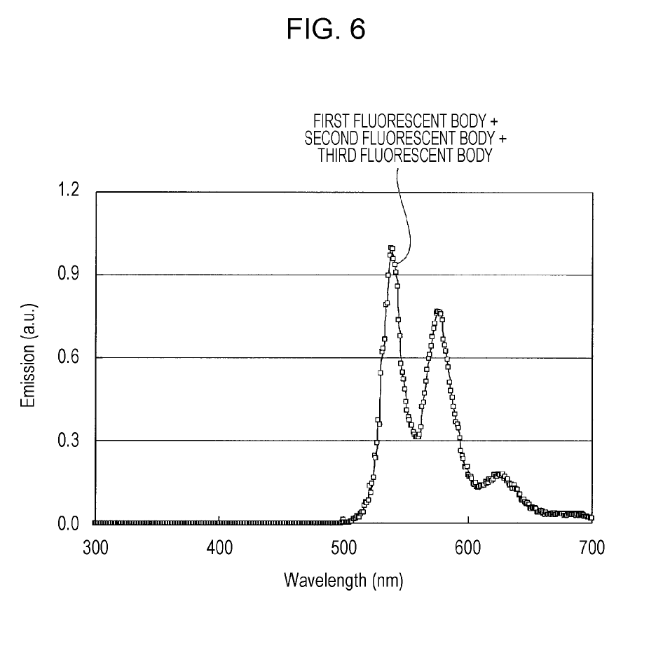

FIGS. 3 to 6 show the emission characteristics and absorption characteristics of the first fluorescent body 8a, the second fluorescent body 8b, and the third fluorescent body 8c serving as the outside light-absorbing optical functional materials. In FIG. 3, the “first fluorescent body” shows a spectrum of sunlight after ultraviolet light has been absorbed by the first fluorescent body 8a. The “second fluorescent body” shows a spectrum of sunlight after blue light has been absorbed by the second fluorescent body 8b. The “third fluorescent body” shows a spectrum of sunlight after green light has been absorbed by the third fluorescent body 8c. In FIG. 4, the “first fluorescent body+second fluorescent body+third fluorescent body” shows a spectrum of sunlight after ultraviolet light, blue light, and green light have been absorbed by the first fluorescent body 8a, the second fluorescent body 8b, and the third fluorescent body 8c. In FIG. 5, the “first fluorescent body” shows an emission spectrum of the first fluorescent body 8a, the “second fluorescent body” shows an emission spectrum of the second fluorescent body 8b, and the “third fluorescent body” shows an emission spectrum of the third fluorescent body 8c. In FIG. 6, the “first fluorescent body+second fluorescent body+third fluorescent body” shows a spectrum of light emitted from a system in which three types of fluorescent bodies, the first fluorescent body 8a, the second fluorescent body 8b, and the third fluorescent body 8c, are mixed with each other.

As shown in FIGS. 3 and 4, the first fluorescent body 8a absorbs light with a wavelength of about 400 nm or less, the second fluorescent body 8b absorbs light with a wavelength of about 400 nm or more and 480 nm or less, and the third fluorescent body 8c absorbs light with a wavelength of about 480 nm or more and 550 nm or less. Of the sunlight that has entered the light guide body, almost all the light with a wavelength of 550 nm or less is absorbed by the first fluorescent body 8a, the second fluorescent body 8b, and the third fluorescent body 8c. The percentage of light with a wavelength of 550 nm or less in the spectrum of sunlight is about 32%. Therefore, 32% of light that has entered the light-entering surface of the light guide body is absorbed by the first fluorescent body 8a, the second fluorescent body 8b, and the third fluorescent body 8c contained in the light guide body.

As shown in FIG. 5, the emission spectrum of the first fluorescent body 8a has a peak wavelength of 430 nm, the emission spectrum of the second fluorescent body 8b has a peak wavelength of 490 nm, and the emission spectrum of the third fluorescent body 8c has a peak wavelength of 540 nm. However, as shown in FIG. 6, the spectrum of light emitted from a system in which three types of fluorescent bodies, the first fluorescent body 8a, the second fluorescent body 8b, and the third fluorescent body 8c, are mixed with each other has only a peak wavelength corresponding to the peak wavelength (540 nm) of the emission spectrum of the third fluorescent body 8c and does not have peak wavelengths corresponding to the peak wavelength (430 nm) of the emission spectrum of the first fluorescent body 8a and the peak wavelength (490 nm) of the emission spectrum of the second fluorescent body 8b.

The peak of the emission spectrum corresponding to the first fluorescent body 8a and the peak of the emission spectrum corresponding to the second fluorescent body 8b have disappeared because of, for example, energy transfer between fluorescent bodies due to photoluminescence (PL) or energy transfer between fluorescent bodies due to a Förster mechanism (fluorescence resonance energy transfer). The energy transfer due to photoluminescence occurs when fluorescence emitted from one fluorescent body is used as excitation energy of another fluorescent body. In the Förster mechanism, excitation energy is directly transferred between two adjacent fluorescent bodies due to resonance of electrons without such emission and absorption processes of light. Since the energy transfer between fluorescent bodies due to the Förster mechanism occurs without emission and absorption processes of light, the energy loss is small under appropriate conditions. This contributes to an improvement in the power generation efficiency of solar cell modules. In this embodiment, for the purpose of efficiently performing power generation by suppressing energy loss, the density of the first fluorescent body 8a, second fluorescent body 8b, and third fluorescent body 8c is increased so that the energy transfer due to the Förster mechanism occurs between fluorescent bodies. The energy transfer is not necessarily completely caused. Although complete energy transfer results in highly efficient power generation, a function as a cell is achieved even with incomplete energy transfer. Even if energy transfer that occurs through emission and absorption processes without the Förster mechanism partly occurs, highly efficient power generation can be performed though the efficiency decreases to some extent.

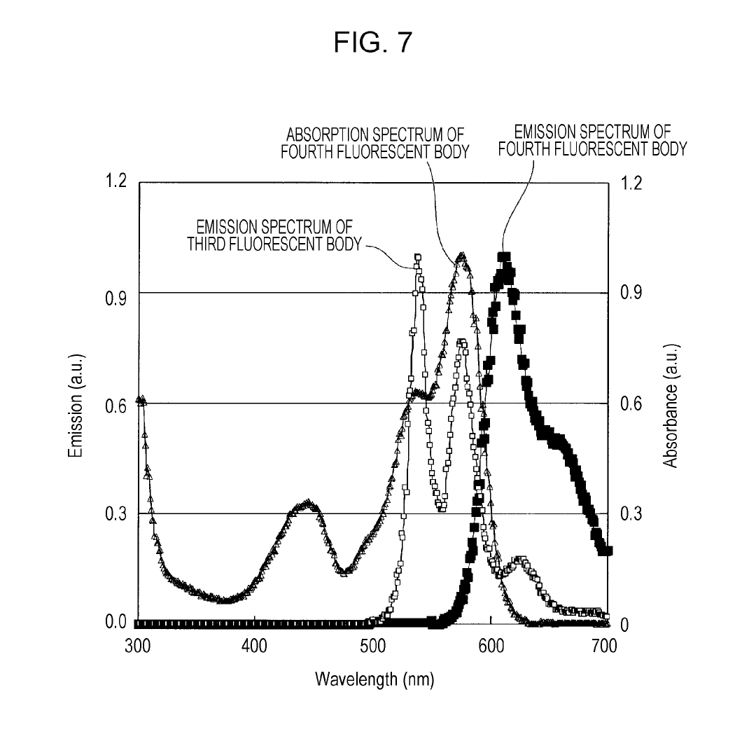

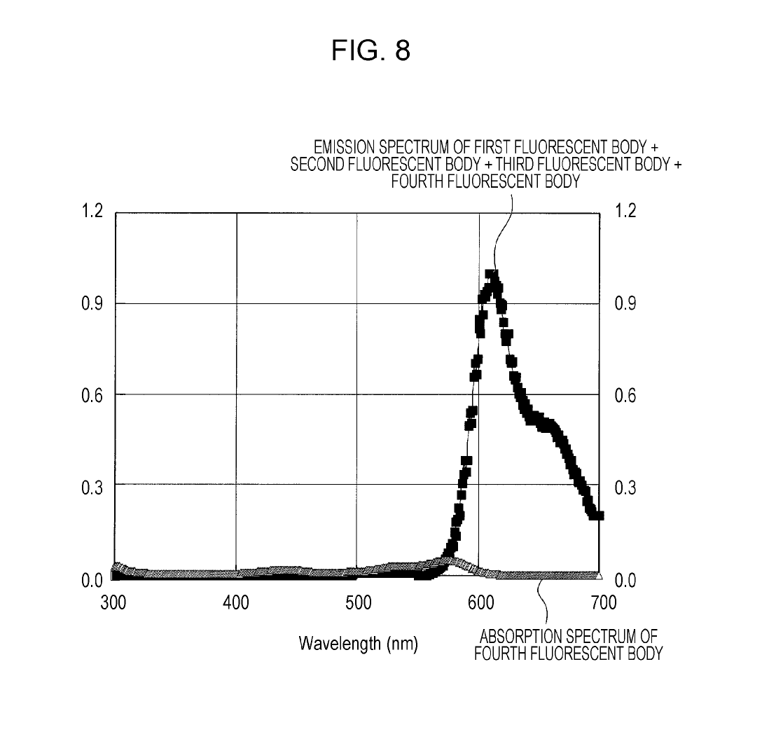

FIG. 7 shows the emission characteristics and absorption characteristics of the fourth fluorescent body 8d serving as the light-guiding optical functional material together with the emission characteristics of the third fluorescent body 8c. FIG. 8 shows the emission characteristics and absorption characteristics of a system in which the outside light-absorbing optical functional materials and the light-guiding optical functional material are mixed with each other.

As shown in FIG. 7, the fourth fluorescent body 8d absorbs light with a wavelength of about 580 nm or less and emits light with a peak wavelength of about 610 nm. The peak wavelength of the absorption spectrum of the fourth fluorescent body 8d and the peak wavelength of the emission spectrum of the third fluorescent body 8c are located very close to each other. The peak wavelength of the emission spectrum of the fourth fluorescent body 8d is about 610 nm and the peak wavelength of the emission spectrum of the third fluorescent body 8c is about 540 nm. However, as shown in FIG. 8, the spectrum of light emitted from the first end surface of the light guide body containing the first fluorescent body 8a, the second fluorescent body 8b, the third fluorescent body 8c, and the fourth fluorescent body 8d has only a peak wavelength corresponding to the peak wavelength (610 nm) of the emission spectrum of the fourth fluorescent body 8d and does not have a peak wavelength corresponding to the peak wavelength (540 nm) of the emission spectrum of the third fluorescent body 8c.

The peak of the emission spectrum corresponding to the third fluorescent body 8c has disappeared because of the above-described energy transfer between fluorescent bodies due to the Förster mechanism. The mixing ratio of the fourth fluorescent body 8d is much smaller than those of other fluorescent bodies (first fluorescent body 8a, second fluorescent body 8b, and third fluorescent body 8c). However, in the Förster mechanism, the energy transfer is often completed even when the concentration of the fluorescent body serving as an acceptor of energy is generally as low as several percent of the concentration of the fluorescent body serving as a donor of energy. Therefore, even if the mixing ratio of the fourth fluorescent body 8d is extremely small, almost 100% of the excitation energy of the first fluorescent body 8a, the second fluorescent body 8b, and the third fluorescent body 8c is transferred to the fourth fluorescent body 8d through the Förster mechanism and thereby high-intensity light is emitted from the fourth fluorescent body 8d.

As is clear from the absorption spectrum of the fourth fluorescent body 8d in FIG. 8, the amount of light absorbed by the fourth fluorescent body 8d is much smaller than the amount of light emitted from the fourth fluorescent body 8d. This is because the mixing ratio of the fourth fluorescent body 8d is extremely small. Therefore, the loss of light caused by self-absorption when the light propagates through the light guide body decreases, and thus highly efficient power generation can be achieved.

In this embodiment, 32% of a spectrum of sunlight that has entered the light guide body is absorbed by the first fluorescent body 8a, the second fluorescent body 8b, and the third fluorescent body 8c. The excitation energy is transferred to the fourth fluorescent body 8d without being wasted. The fourth fluorescent body 8d has the highest fluorescence quantum yield of all the fluorescent bodies contained in the light guide body, and the fluorescence quantum yield is 95%. Therefore, the excitation energy transferred to the fourth fluorescent body 8d is converted into light in the fourth fluorescent body 4d at a high fluorescence quantum yield of 95%. The light emitted from the fourth fluorescent body 8d propagates uniformly in all directions. Herein, since the output loss due to the difference in refractive index between the light guide body and the air layers (the ratio of light emitted from the first principal surface and second principal surface of the light guide body) is 25% and the loss generated during reflection at the reflective layer disposed on the second principal surface is about 4%, the energy that reaches a solar cell element is about 22% of the sunlight that has entered the light guide body. This energy of 22% can be used for power generation of the solar cell element because almost no self-absorption is caused during light guiding.

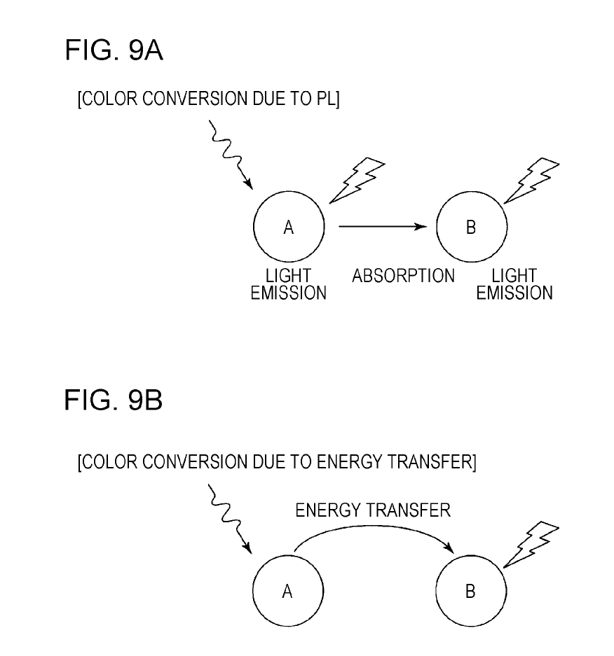

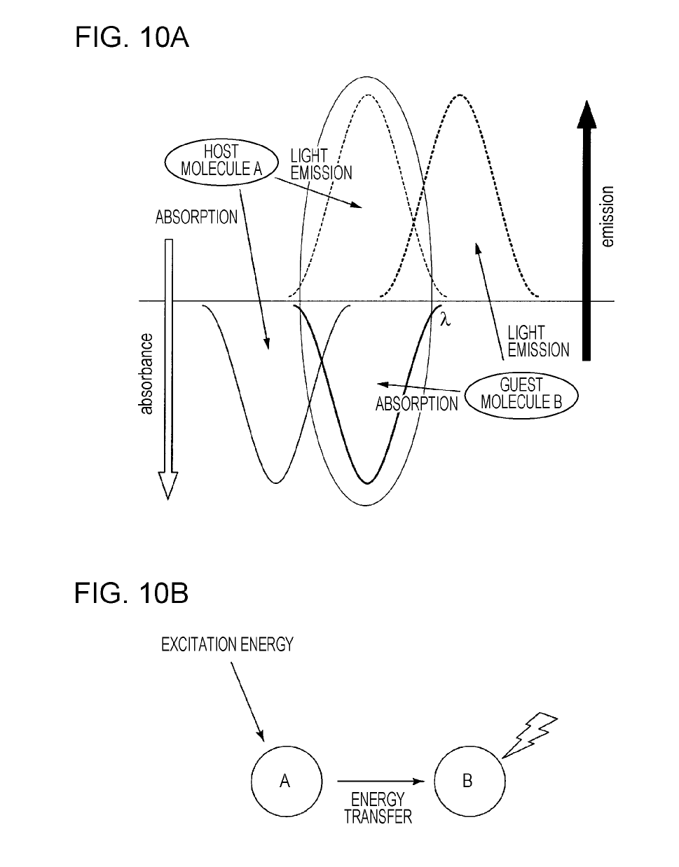

The Förster mechanism will be described with reference to FIGS. 9A to 10B. FIG. 9A is a diagram showing energy transfer due to photoluminescence. FIG. 9B is a diagram showing energy transfer due to the Förster mechanism. FIG. 10A is a diagram for describing the generation mechanism of energy transfer due to the Förster mechanism. FIG. 10B is a diagram showing energy transfer due to the Förster mechanism.

As shown in FIG. 9B, in a fluorescent body composed of organic molecules or inorganic nanoparticles, energy transfer sometimes occurs from a molecule A in an excited state to a molecule B in the ground state through the Förster mechanism. In a fluorescent body, when energy transfer to the molecule B occurs when the molecule A is excited, the molecule B emits light. This energy transfer is dependent on the distance between the molecules, the emission spectrum of the molecule A, and the absorption spectrum of the molecule B. When the molecule A is referred to as a host molecule and the molecule B is referred to as a guest molecule, the rate constant k_{H→G} (transfer probability) in energy transfer is represented by formula (1).

$$\begin{matrix}[ Math . 1 ] & \\ {k}_{H \to G} = \frac{9000 {K}^{2} ln 10}{128 {π}^{5} {n}^{4} N {τ}_{0} {R}^{6}} \int \frac{{f}_{H}^{′} ( v ) ɛ ( v ) d v}{{v}^{4}} & ( 1 )\end{matrix}$$

In the formula (1), ν represents a frequency, f′_{H}(ν) represents the emission spectrum of the host molecule A, ∈(ν) represents the absorption spectrum of the guest molecule B, N represents an Avogadro's constant, n represents a refractive index, τ₀ represents the fluorescence lifetime of the host molecule A, R represents a distance between the molecules, and K² represents a transition dipole moment (⅔ when random).

A high rate constant facilitates energy transfer between fluorescent bodies. To achieve a high rate constant, the following conditions are desirably satisfied.

[1] The emission spectrum of the host molecule A and the absorption spectrum of the guest molecule overlap each other in a large region.
[2] The absorption coefficient of the guest molecule B is large.
[3] The distance between the host molecule A and the guest molecule B is small.

The condition [1] indicates ease of resonance between two adjacent fluorescent bodies. For example, as shown in FIG. 10A, when the peak wavelength of the emission spectrum of the host molecule A is close to the peak wavelength of the absorption spectrum of the guest molecule B, energy transfer due to the Förster mechanism readily occurs. As shown in FIG. 10B, when the guest molecule B in the ground state is present close to the host molecule A in an excited state, the wave function of the guest molecule A changes due to resonant characteristics, which provides a host molecule A in the ground state and a guest molecule B in an excited state. As a result, energy transfer occurs between the host molecule A and the guest molecule B, and the guest molecule B emits light.

In the condition [3], the intermolecular distance at which the energy transfer due to the Förster mechanism occurs is normally about 10 nm Under favorable conditions, the energy transfer occurs even if the intermolecular distance is about 20 nm. If the above-described mixing ratios of the first fluorescent body, the second fluorescent body, and the third fluorescent body are employed, the distance between the fluorescent bodies is less than 20 nm Therefore, the energy transfer due to the Förster mechanism can sufficiently occur. The emission spectra and absorption spectra of the first fluorescent body, the second fluorescent body, the third fluorescent body, and the fourth fluorescent body shown in FIGS. 3 to 7 sufficiently satisfy the condition [1]. This causes the energy transfer from the first fluorescent body to the second fluorescent body, the energy transfer from the second fluorescent body to the third fluorescent body, and the energy transfer from the third fluorescent body to the fourth fluorescent body. That is, cascaded energy transfer occurs in the order of the first fluorescent body, the second fluorescent body, the third fluorescent body, and the fourth fluorescent body.

In the light guide body, substantially only the fourth fluorescent body emits light as a result of the energy transfer due to the Förster mechanism despite the fact that fluorescent bodies having four different emission spectra (first fluorescent body, second fluorescent body, third fluorescent body, and fourth fluorescent body) are mixed into the light guide body. The fluorescence quantum yield of the fourth fluorescent body is, for example, 95%. Therefore, by mixing the first fluorescent body, the second fluorescent body, the third fluorescent body, and the fourth fluorescent body into the light guide body, light with a wavelength of up to 550 nm is absorbed and red light with a peak wavelength of 610 nm can be emitted at an efficiency of 95%.

Such an energy transfer phenomenon is a phenomenon unique to organic fluorescent bodies and is generally believed not to occur in inorganic fluorescent bodies. However, some fluorescent bodies composed of inorganic nanoparticles, such as quantum dots, are known to cause energy transfer between inorganic materials or between an inorganic material and an organic material through the Förster mechanism.

For example, energy transfer occurs between quantum dots having two different sizes with a ZnO/MgZnO core-shell structure. Quantum dots having a size ratio of 1:√2 have resonance exciton levels. Therefore, in two types of quantum dots, for example, having a radius of 3 nm (peak wavelength of emission spectrum: 350 nm) and a radius of 4.5 nm (peak wavelength of emission spectrum: 357 nm), energy transfer occurs from the small quantum dot to the large quantum dot. Similarly, energy transfer occurs between quantum dots having two different sizes with a CdSe/ZnS core-shell structure. Furthermore, a Mn²⁺-doped ZnSe quantum dot having a diameter of 8 nm or 9 nm has emission peaks at 450 nm and 580 nm, and such a spectrum highly matches the light absorption spectrum of a ring-opened spiropyran molecule (SPO open; merocynanine form) obtained by applying ultraviolet rays to 1′,3′-dihydro-1′,3′,3′-trimethyl-6-nitrospiro[2H-1-benzopyran-2,2′-(2H)-indole], which is a dye molecule. Thus, energy transfer occurs from the quantum dot to the dye molecule. In general, inorganic fluorescent bodies are advantageous when used for a long time because they have better light resistance than organic fluorescent bodies.

Normally, when two types of fluorescent bodies are mixed, a fluorescent body A emits light at a certain efficiency, the light enters a fluorescent body B, and light absorption and light emission occur in the fluorescent body B as shown in FIG. 9A. Consequently, light is emitted from the fluorescent body B. In such energy transfer due to photoluminescence, energy transfer efficiency is low because energy is lost in the light emission process in the fluorescent body A and in the light absorption process in the fluorescent body B.

On the other hand, in the energy transfer due to the Förster mechanism shown in FIG. 9B, only energy is directly transferred between fluorescent bodies. Therefore, the energy transfer efficiency is almost 100%, and thus energy transfer can be caused with high efficiency.

The energy transfer due to the Förster mechanism occurs not only in luminous materials such as fluorescent bodies, but also in nonluminous bodies that are excited by outside light but deactivate without emitting light. The amount of power generation in the end is determined by the fluorescence quantum yield of guest molecules and is not dependent on the fluorescence quantum yield of host molecules. Therefore, as long as a fluorescent body with a high fluorescence quantum yield is used for the guest molecule, the amount of power generation is the same even if a fluorescent body with a low fluorescence quantum yield or a nonluminous body that does not emit fluorescence is used for the host molecule. Therefore, a variety of materials can be selected for the host molecule compared with the case where a high fluorescence quantum yield is required for all fluorescent bodies as in the case of energy transfer due to photoluminescence.

A relationship between concentration and intermolecular distance that can cause energy transfer in the first fluorescent body 8a, the second fluorescent body 8b, the third fluorescent body 8c, and the fourth fluorescent body 8d according to this embodiment will be described. The intermolecular distance that can cause energy transfer is 15 nm to 20 nm at most and desirably 10 nm or less. When a PMMA resin having a density of 1.17 to 1.4 is used as the light guide body, the concentrations of host molecules corresponding to the maximum intermolecular distance (20 nm) are 0.03 wt % in the first fluorescent body 8a, 0.05 wt % in the second fluorescent body 8b, 0.07 wt % in the third fluorescent body 8c, and 0.1 wt % in the fourth fluorescent body 8d. The concentrations of host molecules corresponding to the desired intermolecular distance (10 nm) are 0.04 wt % in the first fluorescent body 8a, 0.07 wt % in the second fluorescent body 8b, 0.10 wt % in the third fluorescent body 8c, and 0.15 wt % in the fourth fluorescent body 8d. Therefore, by mixing fluorescent bodies with concentrations higher than or equal to the above-mentioned concentrations, energy transfer due to the Förster mechanism smoothly occurs.

Even if the ratio of the guest molecule to the host molecule is about 10% to 2%, almost 100% of energy transfer due to the Förster mechanism occurs. For example, even if the mixing ratio of the fourth fluorescent body serving as a light-guiding optical functional material is 10% or less of the mixing ratio of at least an optical functional material having the largest mixing ratio among the first fluorescent body, the second fluorescent body, and the third fluorescent body serving as outside light-absorbing optical functional materials or 10% or less of the mixing ratio of an optical functional material having the smallest mixing ratio among the first fluorescent body, the second fluorescent body, and the third fluorescent body serving as outside light-absorbing optical functional materials, almost 100% of energy transfer due to the Förster mechanism occurs.

The concentrations of the first fluorescent body, the second fluorescent body, the third fluorescent body, and the fourth fluorescent body serving as optical functional materials are preferably as low as possible because the amount of self-absorption decreases as the concentrations are decreased. For example, when the concentration of each of the fluorescent bodies is 0.3 wt % or less, the self-absorption can be favorably suppressed.

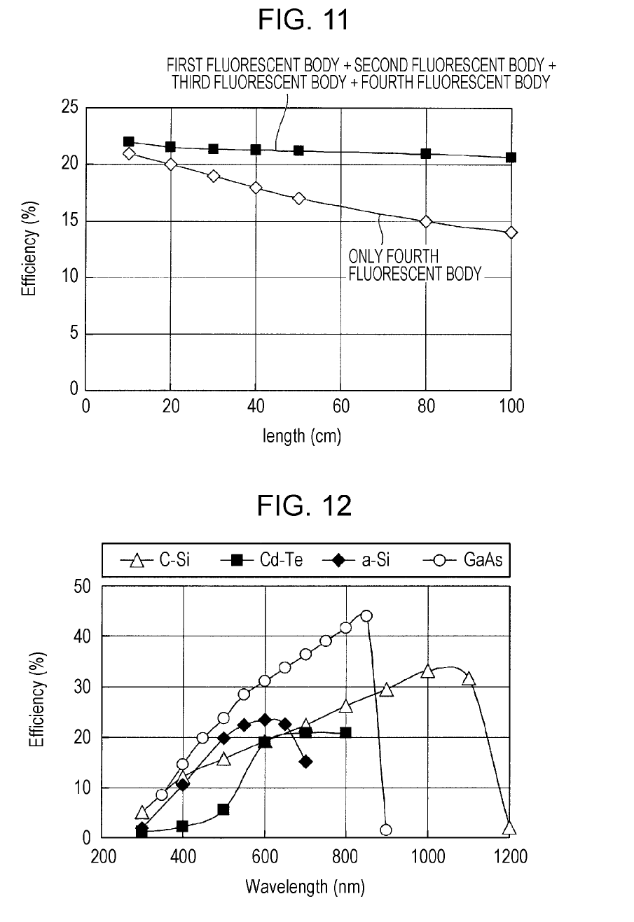

FIG. 11 shows a relationship between the size of the light guide body (the propagation optical path length of light propagating through the light guide body) and the light output efficiency from the end surface of the light guide body. In FIG. 11, the “fourth fluorescent body” indicates the case where only the fourth fluorescent body is mixed into the light guide body at a high mixing ratio in order to use the fourth fluorescent body not only as a light-guiding optical functional material but also as an outside light-absorbing optical functional material. The “first fluorescent body+second fluorescent body+third fluorescent body+fourth fluorescent body” indicates the case where the first fluorescent body, the second fluorescent body, the third fluorescent body, and the fourth fluorescent body are mixed into the light guide body at the above-described mixing ratios in order to use the fourth fluorescent body only as a light-guiding optical functional material.

As shown in FIG. 11, in the case where only one type of fluorescent body is mixed into the light guide body, the light output efficiency is considerably decreased as the size of the light guide body increases. This is because of the self-absorption of the fluorescent body. On the other hand, in the case where a fluorescent body used only as a light-guiding optical functional material is mixed into the light guide body, the light output efficiency substantially does not change even if the size of the light guide body increases.

FIG. 12 shows the energy conversion efficiency ix, of various solar cells that can be used as the solar cell element 6. In FIG. 12, “c-Si” indicates a monocrystalline silicon solar cell, “a-Si” indicates an amorphous silicon solar cell, “GaAs” indicates a gallium arsenide solar cell, and “CdTe” indicates a cadmium telluride solar cell.

The photoelectric conversion efficiency of solar cells is known to have wavelength dependence in accordance with the spectral sensitivity of solar cells used. The generally-used conversion efficiency is an average conversion efficiency with respect to all wavelengths of sunlight. Therefore, when the wavelength of light emitted from the first end surface is limited to a particular wavelength as in this embodiment, the power generation is performed at a conversion efficiency based on the wavelength of the emitted light. In this embodiment, since the light emitted from the first end surface is light in a wavelength range of 610 nm to 650 nm, the power generation is performed at a conversion efficiency in such a wavelength range.

In the solar cells shown in FIG. 12, the spectral sensitivity and energy conversion efficiency of the solar cells at the peak wavelength (610 nm) of the emission spectrum of the fourth fluorescent body 8d, which has the longest peak wavelength of the emission spectrum, are higher than the spectral sensitivity and energy conversion efficiency of the solar cells at the peak wavelengths of the emission spectra of any other fluorescent bodies (first fluorescent body 8a, second fluorescent body 8b, and third fluorescent body 8c) contained in the light guide body 4. Therefore, highly efficient power generation can be performed by using these solar cells as the solar cell element 6.

FIG. 12 shows examples of the solar cells that can be used as the solar cell element 6, and solar cells other than the above-described solar cells can be obviously used. Solar cells such as dye-sensitized solar cells and organic solar cells can also be actively used as the solar cell element 6. Such dye-sensitized solar cells and organic solar cells are solar cells that do not have a high spectral sensitivity in the entire wavelength range of sunlight but has a considerably high spectral sensitivity to light in a particular narrow wavelength range.

Table 1 shows the conversion efficiency, the amount of power generation, and the cost per watt when the light guide body (fluorescence guide body) of this embodiment and each of the solar cells shown in FIG. 12 are combined with each other.

In Table 1, “the case where fluorescence guide body is used” means that power generation is performed by using a solar cell disposed on the end surface of a fifty-centimeter-square fluorescence guide body having the structure of this embodiment. “The case where fluorescence guide body is not used” means that power generation is not performed by using the fluorescence guide body but rather is performed by using a solar cell having the same area (50 cm square) as the fluorescence guide body. In the case where the fluorescence guide body is used, the conversion efficiency of the solar cell is a conversion efficiency at the emission wavelength of the light-guiding optical functional material. In the case where the fluorescence guide body is not used, the conversion efficiency of the solar cell is an average conversion efficiency in the entire wavelength range of the spectrum of sunlight.

TABLE 1

| | | Conversion | Amount of | Cost per |
|---|---|---|---|---|
| | Conversion | efficiency | power | watt in |
| | efficiency in | in the case | generation in | the case |
| | the case where | where | the case where | where |
| | fluorescence | fluorescence | fluorescence | fluorescence |
| Type of | guide body is | guide body | guide body is | guide body |
| solar cell | not used | is used | used | is used |
| Crystalline | 15% | 16% | 35 W/m² | 160 yen/W |
| Si | | | | |
| α-Si | 8.5% | 18% | 40 W/m² | 130 yen/W |
| CdTe | 9% | 20% | 44 W/m² | 130 yen/W |
| GaAs | 24% | 32% | 70 W/m² | 175 yen/W |
| (monolayer) | | | | |

As shown in Table 1, in the case where the fluorescence guide body is used, sunlight is converted into light with a wavelength suitable for the spectral sensitivity of each solar cell and made to enter the solar cell. Therefore, the conversion efficiency of each solar cell is higher than that in the case where the fluorescence guide body is not used. In reality, only about 22% of light that has entered the light-entering surface of the fluorescence guide body is guided to the end surface of the fluorescence guide body. Consequently, the amount of power generation is smaller than that in the case where the fluorescence guide body is not used. However, in consideration of the installation cost of a solar cell module per unit area, the cost per watt is as low as 130 yen/W to 175 yen/W and the amount of power generation corresponding to the cost is achieved.

In this embodiment, 32% of sunlight is converted into fluorescence using three types of outside light-absorbing fluorescent bodies. In principle, almost all the sunlight can be converted into fluorescence by increasing the types of fluorescent bodies. In this case, even if the losses during light guiding (the output loss due to the difference in refractive index between the fluorescence guide body and the air layers and the loss generated during reflection at the reflective layer disposed on the second principal surface of the fluorescence guide body) are taken into consideration, about 70% of sunlight can be converted into fluorescence. Therefore, considering the advantage in terms of conversion efficiency, the amount of power generation compares favorably with that in the case where the fluorescence guide body is not used.

The case where the fifty-centimeter-square fluorescence guide body is used is shown in Table 1. If the size of the fluorescence guide body is increased, the cost per watt is further decreased. In general, when the size of the fluorescence guide body is increased, the loss caused by self-absorption when light propagates through the fluorescence guide body increases. Consequently, the cost per watt does not decrease as well as expected. In this embodiment, however, since the light-guiding optical functional material has a considerably low concentration, the loss caused by self-absorption is small and the cost per watt decreases mostly inversely proportionally to the size of the fluorescence guide body.

As described above, in the light guide body 4 according to this embodiment, part of outside light L that has entered the light-entering surface 4a is absorbed by a plurality of optical functional materials (first fluorescent body 8a, second fluorescent body 8b, third fluorescent body 8c, and fourth fluorescent body 8d); energy transfer due to the Förster mechanism is caused between the plurality of optical functional materials; and light L1 emitted from an optical functional material (fourth fluorescent body 8d) having the longest peak wavelength of the emission spectrum is made to enter the solar cell element 6 while being concentrated at the first end surface 4c of the light guide body 4. Therefore, solar cells having a considerably high spectral sensitivity in a limited narrow wavelength range can be used as the solar cell element 6.

In the solar cell module 1 according to this embodiment, the spectral sensitivity of the solar cell element 6 at the peak wavelength of the emission spectrum of the fourth fluorescent body 8d having the longest peak wavelength of the emission spectrum among the plurality of fluorescent bodies contained in the light guide body 4 is larger than the spectral sensitivities of the solar cell element 6 at the peak wavelengths of the emission spectra of any other fluorescent bodies (first fluorescent body 8a, second fluorescent body 8b, and third fluorescent body 8c) contained in the light guide body 4. Therefore, highly efficient power generation can be performed.

Furthermore, since the content of the fourth fluorescent body 8d in the light guide body 4 is lower than those of any other optical functional materials, the self-absorption is not easily caused by the fourth fluorescent body 8d when the light L1 emitted from the fourth fluorescent body 8d propagates through the light guide body 4. Therefore, power generation with higher efficiency can be achieved.

### Second Embodiment

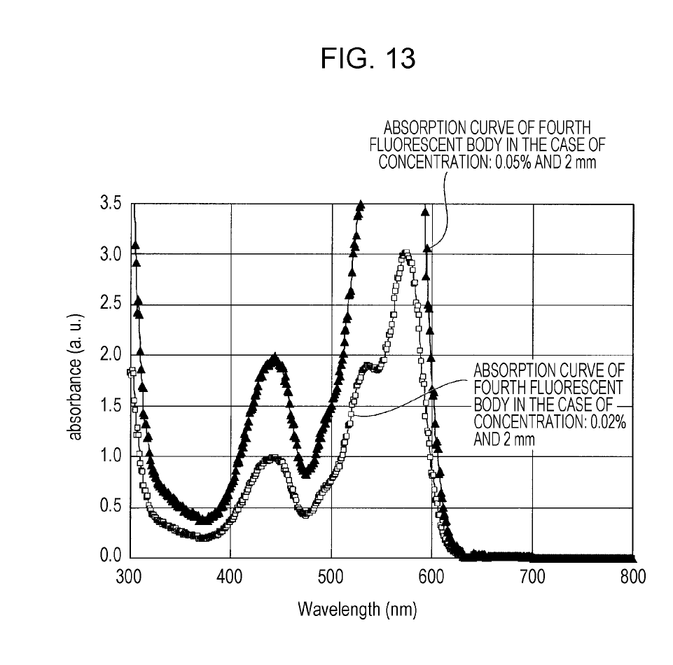

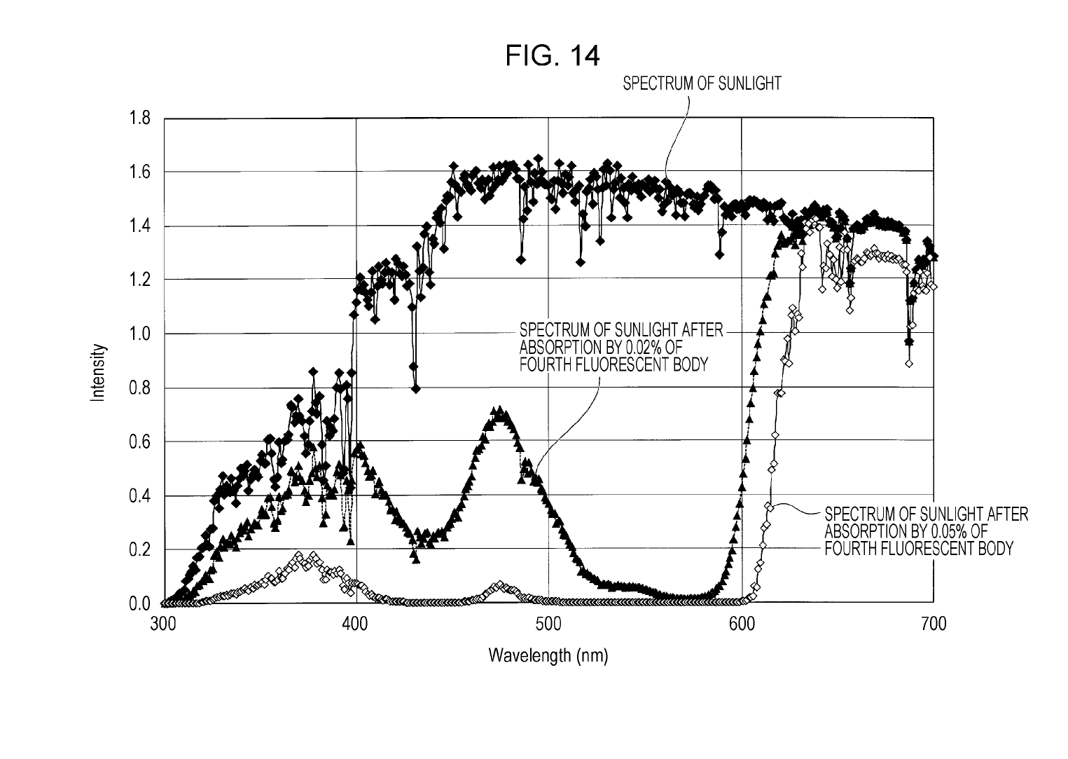

FIGS. 13 and 14 show the absorption characteristics of outside light-absorbing optical functional materials used in a solar cell module according to a second embodiment.

This embodiment is different from the first embodiment in that the above-described fourth fluorescent body is used as an outside light-absorbing optical functional material and a fifth fluorescent body is used as a light-guiding optical functional material. In the first embodiment, since the mixing ratio of the fourth fluorescent body (the volume ratio relative to a PMMA resin included in the light guide body) is extremely small, the fourth fluorescent body substantially does not function as an outside light-absorbing optical functional material, but functions only as a light-guiding optical functional material. On the other hand, in this embodiment, the fourth fluorescent body is dispersed in the light guide body at a high concentration to use the fourth fluorescent body as an outside light-absorbing optical functional material.

In FIG. 13, referring to the absorption spectrum of a light guide body having a thickness of 2 mm and containing the fourth fluorescent body at a mixing ratio of 0.02%, the absorbance of a main peak located around 570 nm is more than 3 and thus sunlight can be sufficiently absorbed. In addition to the main peak, the fourth fluorescent body has a broad absorption peak at a center wavelength of 450 nm. At a mixing ratio of 0.02%, it is difficult to sufficiently absorb sunlight. However, when the mixing ratio is increased to 0.05%, the absorbance of the peak at 450 nm exceeds 2 and thus 99% or more of light can be absorbed. In other words, the fourth fluorescent body alone can absorb most of light with a wavelength of up to 600 nm

FIG. 14 shows a spectrum of sunlight after the sunlight passes through the light guide body. Referring to the spectra in FIG. 14, when the mixing ratio of the fourth fluorescent body is 0.02%, light in a wavelength range of 520 nm to 600 nm can be sufficiently absorbed, but light in a wavelength range of 500 nm or less cannot be sufficiently absorbed. On the other hand, when the mixing ratio of the fourth fluorescent body is 0.05%, light in a wavelength range of 300 nm to 600 nm is sufficiently absorbed. Therefore, when the mixing ratio of the fourth fluorescent body is 0.05% or more, the fourth fluorescent body can be sufficiently used as an outside light-absorbing optical functional material.

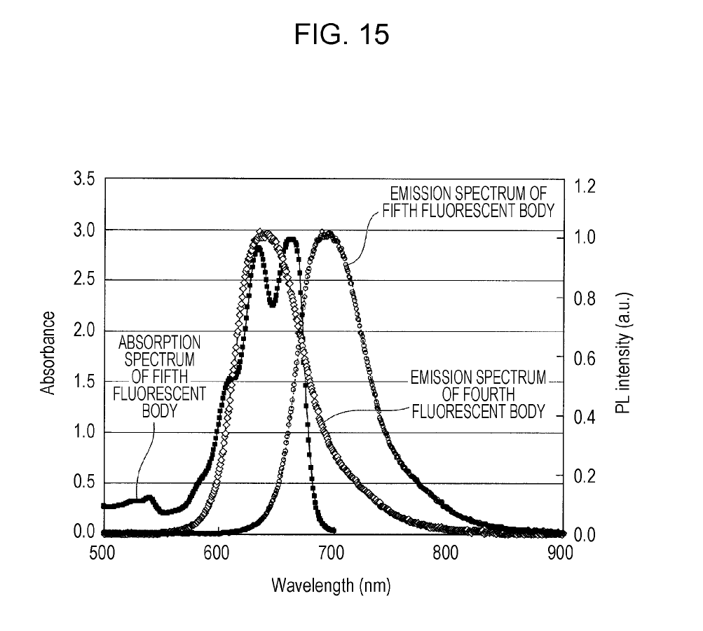

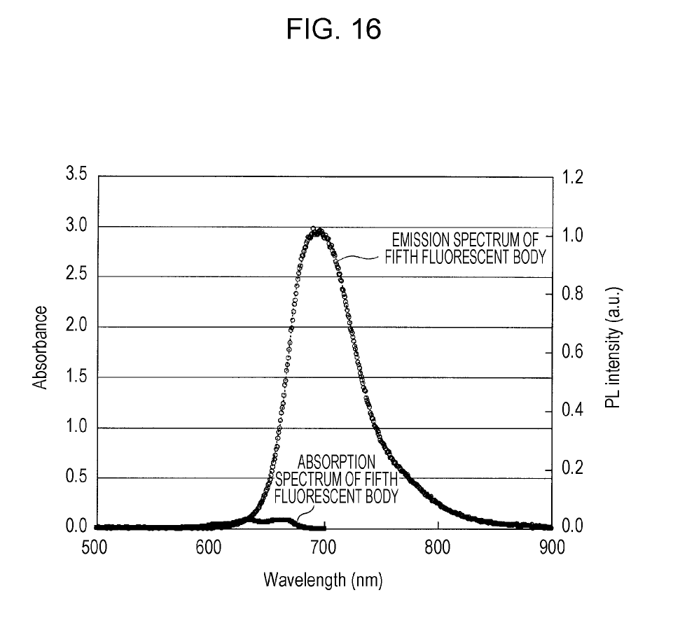

FIG. 15 shows the emission characteristics and absorption characteristics of a light-guiding optical functional material used in this embodiment together with the emission characteristics of the fourth fluorescent body. FIG. 16 shows the emission characteristics and absorption characteristics of a system in which the outside light-absorbing optical functional material and the light-guiding optical functional material are mixed.

In this embodiment, a fifth fluorescent body is used as the light-guiding optical functional material. The fifth fluorescent body is composed of a perylene derivative and is, for example, a fluorescent body having a chemical structure represented by chemical structural formula (i) or chemical structural formula (ii). By changing a substituent X in the chemical structural formula (i) or a substituent R in the chemical structural formula (ii), the emission characteristics and the absorption characteristics are controlled.

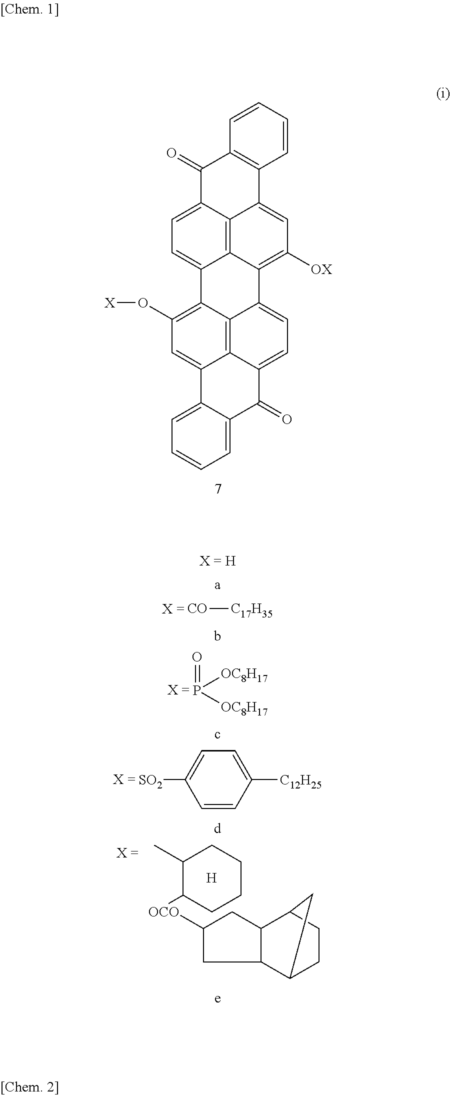

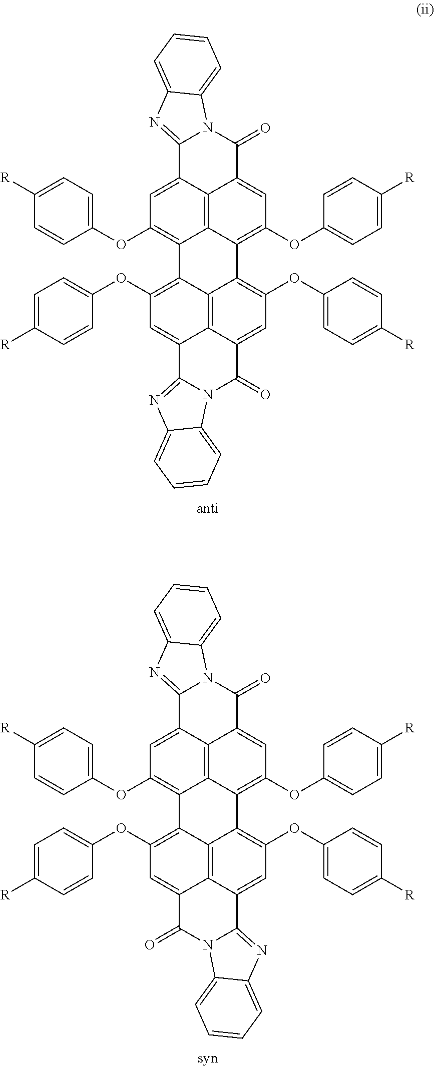

As shown in FIG. 15, the fifth fluorescent body absorbs light in a wavelength range of about 600 nm to 670 nm and emits light having a peak wavelength of about 700 nm. The peak wavelength of the absorption spectrum of the fifth fluorescent body and the peak wavelength of the emission spectrum of the fourth fluorescent body 8d are located very close to each other. Therefore, energy transfer efficiently occurs from the fourth fluorescent body to the fifth fluorescent body.

In this embodiment, the mixing ratio of the fourth fluorescent body is 0.2% and the mixing ratio of the fifth fluorescent body is 0.005%. The ratio of the fifth fluorescent body to the fourth fluorescent body is about 2.5%, and the content of the fifth fluorescent body in a binder resin of the light guide body is only 0.0025%. Therefore, the fifth fluorescent body substantially does not function as an outside light-absorbing optical functional material, but functions only as a light-guiding optical functional material.

As shown in FIG. 16, high-intensity light is emitted from the fifth fluorescent body as a result of energy transfer from the fourth fluorescent body, but only a small amount of light is absorbed by the fifth fluorescent body. This is because the amount of light emitted from the fifth fluorescent body is amplified by excitation energy transfer from the fourth fluorescent body whereas the amount of light absorbed by the fifth fluorescent body is dependent on the mixing ratio of the fifth fluorescent body. Therefore, the light emitted from the fifth fluorescent body is concentrated at the first end surface of the light guide body while hardly undergoing self-absorption during light guiding.

In this embodiment, 30% of a spectrum of sunlight that has entered the light guide body is absorbed by the fourth fluorescent body. The excitation energy is transferred to the fifth fluorescent body without being wasted. The fluorescence quantum yield of the fifth fluorescent body is 90%. Therefore, the excitation energy transferred to the fifth fluorescent body is converted into light in the fifth fluorescent body at a high fluorescence quantum yield of 90%. The light emitted from the fifth fluorescent body propagates uniformly in all directions. Herein, since the output loss due to the difference in refractive index between the light guide body and the air layers (the ratio of light emitted from the first principal surface and second principal surface of the light guide body) is 25% and the loss generated during reflection at the reflective layer disposed on the second principal surface is about 4%, the energy that reaches a solar cell element is about 20% of the sunlight that has entered the light guide body. This energy of 20% can be used for power generation of the solar cell element because almost no self-absorption is caused during light guiding.

Table 2 shows the conversion efficiency, the amount of power generation, and the cost per watt when the light guide body (fluorescence guide body) of this embodiment and each of the solar cells shown in FIG. 12 are combined with each other. In Table 2, “the case where fluorescence guide body is used” and “the case where fluorescence guide body is not used” have the same meaning as in Table 1.

TABLE 2

| | | Conversion | Amount of | Cost per |
|---|---|---|---|---|
| | Conversion | efficiency | power | watt in |
| | efficiency in | in the case | generation in | the case |
| | the case where | where | the case where | where |
| | fluorescence | fluorescence | fluorescence | fluorescence |
| Type of | guide body is | guide body | guide body is | guide body |
| solar cell | not used | is used | used | is used |
| Crystalline | 15% | 16% | 32 W/m² | 165 yen/W |
| Si | | | | |
| α-Si | 8.5% | 18% | 36 W/m² | 135 yen/W |
| CdTe | 9% | 20% | 40 W/m² | 135 yen/W |
| GaAs | 24% | 32% | 64 W/m² | 180 yen/W |
| (monolayer) | | | | |

As shown in Table 2, also in this embodiment, the conversion efficiency in the case where the fluorescence guide body is used is higher than that in the case where the fluorescence guide body is not used. Furthermore, since the loss due to self-absorption during light guiding is small, high power generation efficiency is achieved and the cost per watt is decreased.

In this embodiment, a single fluorescent body is used as the outside light-absorbing optical functional material. The absorption wavelength range can be widened by using a plurality of outside light-absorbing optical functional materials as in the first embodiment, but the energy transfer sometimes does not completely occur or it is sometimes difficult to efficiently cause energy transfer among all fluorescent bodies. In such a case, if the amount of light absorbed can be adjusted by using a single fluorescent body having a somewhat wide absorption wavelength range and adjusting the mixing ratio, such problems can be suppressed.

In this embodiment, only the fourth fluorescent body is used as the outside light-absorbing fluorescent body. However, there is a region in which the amount of light absorbed is smaller than that in the first embodiment. Therefore, the amount of power generation can be increased by mixing another fluorescent body to compensate for a region in which the amount of light absorbed by the fourth fluorescent body is small. For example, by mixing 0.02% of the above-described first fluorescent body into the structure of this embodiment, all of the small amount of the sunlight with a wavelength of 300 nm to 400 nm that cannot be absorbed by using only the fourth fluorescent body can be absorbed. In this case, the light output efficiency from the first end surface of the light guide body is slightly improved, and the amount of power generation is 66 W/m² in simulation.

A sixth fluorescent body, which is a derivative of the fifth fluorescent body, may be mixed into the structure of this embodiment in an amount of 0.005%. The sixth fluorescent body is a fluorescent body having a chemical structure represented by the chemical structural formula (i) or the chemical structural formula (ii). By changing a substituent X in the chemical structural formula (i) or a substituent R in the chemical structural formula (ii), the emission characteristics and absorption characteristics of the sixth fluorescent body are controlled so as to have intermediate characteristics between the fourth fluorescent body and the fifth fluorescent body.

Since the sixth fluorescent body is mixed only in a trace amount, the sixth fluorescent body substantially does not function as the outside light-absorbing optical functional material. The sixth fluorescent body is mixed in order to assist the energy transfer from the fourth fluorescent body to the fifth fluorescent body. In the case where energy transfer does not appropriately occur from the fourth fluorescent body to the fifth fluorescent body due to a spectrum shift or nonuniformity in resin, the presence of the sixth fluorescent body having intermediate characteristics between the fourth fluorescent body and the fifth fluorescent body can smoothly cause energy transfer in the order of the fourth fluorescent body, the sixth fluorescent body, and the fifth fluorescent body. In this case, the amount of power generation is 66 W/m² in simulation.

### Third Embodiment

This embodiment is different from the first embodiment in that three types of fluorescent bodies, a seventh fluorescent body, the second fluorescent body, and the third fluorescent body, are used as outside light-absorbing optical functional materials. The second fluorescent body and the third fluorescent body are the same as those described above.

The seventh fluorescent body is a fluorescent body (N,N′-bis-(1-naphthalenyl)-N,N′-bis-phenyl-(1,1′-biphenyl)-4,4′-diamine, NPB) having a chemical structure represented by chemical structural formula (iii). The seventh fluorescent body has emission characteristics and absorption characteristics similar to those of the first fluorescent body, and energy transfer occurs from the seventh fluorescent body to the second fluorescent body through the Förster mechanism. However, the fluorescence quantum yield of the seventh fluorescent body is 42%, which is lower than the fluorescence quantum yield 95% of the first fluorescent body. The seventh fluorescent body has higher resistance to infrared light than the first fluorescent body.

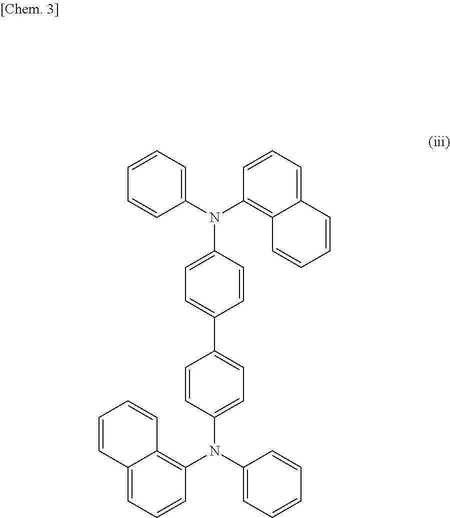 [SMILES: c1ccc(N(c2ccc(-c3ccc(N(c4ccccc4)c4cccc5ccccc45)cc3)cc2)c2cccc3ccccc23)cc1]

The seventh fluorescent body has a fluorescence quantum yield lower than that of the first fluorescent body. However, in the process of energy transfer due to the Förster mechanism, energy is transferred to a guest fluorescent body before a host fluorescent body emits light. Therefore, energy transfer efficiently occurs regardless of the fluorescence quantum yield of the host fluorescent body. Consequently, energy is efficiently transferred to the second fluorescent body in the same manner, regardless of the use of the seventh fluorescent body or the first fluorescent body as an outside light-absorbing optical functional material. The amount of power generation in the case of the seventh fluorescent body is substantially the same as the amount of power generation in the case of the first fluorescent body.

In this embodiment, the seventh fluorescent body has a very small fluorescence quantum yield of 42%. However, in the energy transfer due to the Förster mechanism, the amount of power generation in the end is determined by the fluorescence quantum yield of guest molecules and is not dependent on the fluorescence quantum yield of host molecules. Therefore, as long as a fluorescent body with a high fluorescence quantum yield is used for the guest molecule, the amount of power generation is the same even if a fluorescent body with a low fluorescence quantum yield is used for the host molecule.

In general, fluorescent bodies are used as luminous bodies and thus fluorescent bodies having a low fluorescence quantum yield cannot be used. However, when only energy is directly transferred without light emission as in this embodiment, such fluorescent bodies having a low fluorescence quantum yield can be used because the amount of power generation in the end is the same. In general, many fluorescent bodies having a high fluorescence quantum yield are expensive and have low light resistance and short lifetime, which increases the maintenance cost. On the other hand, fluorescent bodies having a low fluorescence quantum yield are inexpensive, are selected from a variety of materials, and have high light resistance and long lifetime, which can decrease the maintenance cost.

The fluorescence quantum yield of the seventh fluorescent body is preferably less than 90% and more preferably 80% or less. In general, the lifetime of solar cells is defined to be a time for which the conversion efficiency reaches 90% of the initial conversion efficiency. Therefore, the lifetime of the light guide body can be regarded as a time for which the emission intensity of the fluorescent body decreases by 10%. Fluorescent bodies are normally supposed to be used as luminous bodies, and thus a high fluorescence quantum yield of 100% to 90% is required. Therefore, the lifetime of fluorescent bodies can be regarded as a time for which the fluorescence quantum yield decreases from the initial fluorescence quantum yield by 10%, that is, a time for which the fluorescence quantum yield reaches 90% to 81%. Consequently, fluorescent bodies having a fluorescence quantum yield of 80% or less are normally not used. If such fluorescent bodies exist, they are available at low cost as low-performance fluorescent bodies. By using such fluorescent bodies having a low fluorescence quantum yield, solar cell modules having high power generation efficiency can be provided at low cost.

As a result of a light resistance test conducted on the solar cell module including the seventh fluorescent body and the solar cell module including the first fluorescent body, it was found that the solar cell module including the seventh fluorescent body had higher light resistance and could maintain a higher power output in a long-term operation. This is because of the difference in light resistance between the first fluorescent body and the seventh fluorescent body. In the solar cell module according to this embodiment, degradation of the fluorescent bodies contained in the light guide body results in degradation of characteristics such as conversion efficiency and the amount of power generation. The light guide body contains a plurality of fluorescent bodies. If any of the fluorescent bodies degrades, the entirety is considerably affected in terms of balance of energy transfer and absorption efficiency of sunlight compared with the case where a single fluorescent body is used, which may facilitate the degradation. Therefore, it is important to use fluorescent bodies having high light resistance.

In energy transfer, the overlap of spectra is important and the quantum yield of each fluorescent body is meaningless. In an extreme case, there is no need of light emission. After all, only the light-guiding optical functional material may efficiently emit light. By selecting a material having high light resistance as in this embodiment, the lifetime of a solar cell module can be lengthened.

When a plurality of fluorescent bodies are used as outside light-absorbing optical functional materials as described above, all or some of the plurality of fluorescent bodies may have a low fluorescence quantum yield. One or more optical functional materials having a fluorescence quantum yield of 80% or less may be included in the plurality of outside light-absorbing optical functional materials as long as at least the light-guiding optical functional material has a high fluorescence quantum yield. In this embodiment, the fluorescence quantum yield of the light-guiding optical functional material is higher than the fluorescence quantum yield of any of the outside light-absorbing optical functional materials, and may be higher than the fluorescence quantum yield of at least an optical functional material which has the lowest fluorescence quantum yield among the one or more outside light-absorbing optical functional materials. Since the fluorescence quantum yield of the outside light-absorbing optical functional materials may be low, a variety of materials can be selected. In particular, when many fluorescent bodies are combined to expand the absorption wavelength of sunlight, it is difficult to highly match the spectra. However, if there are conditions that the fluorescence quantum yield may be low, a variety of materials can be selected. Furthermore, materials with high durability and low-cost materials can be selected, and consequently a solar cell module with high light resistance and a high power output can be provided at low cost.

In this embodiment, NPB has been exemplified as the optical functional material that has a low fluorescence quantum yield but is applicable to the light guide body in this embodiment. However, the optical functional material that is applicable to the light guide body in this embodiment is not limited thereto. Non-limiting examples of other materials include organic fluorescent bodies such as N,N′-bis(3-methylphenyl)-N,N′-diphenyl-[1,1′-biphenyl]-4,4′-diamine (TPD), 4,4′-bis-[N-(1-naphthyl)-N-phenylamino]-biphenyl) (a-NPD), 4,4′-bis-[N-(9-phenanthyl)-N-phenylamino]-biphenyl (PPD), N,N,N′,N′-tetra-tolyl-1,1′-cyclohexyl-4,4′-diamine (TPAC), 1,1,4,4-tetraphenyl-1,3-butadiene (TPB), TACP, poly(N-vinylcarbazole) (PVK), 4,4′,4″-tri(N-carbazolyl)triphenylamine (TCTA), 1,3,5-tris[4-(3-methylphenylphenylamino)phenyl]benzene (m-MTDAPB), 1,3,5-tris[N-(4-diphenylaminophenyl)phenylamino]benzene (p-DPA-TDAB), 4,4,4″-tris(3-methylphenylphenylamino)triphenylamine (m-MTDATA), 4,4′,4″-tris(1-naphthylphenylamino)triphenylamine (1-TNATA), 4,4′,4″-tris(2-naphthylphenylamino)triphenylamine (2-TNATA), 1,3,5-tris(4-tert-butylphenyl-1,3,4-oxadiazolyl)benzene (TPOB), tri(p-terphenyl-4-yl)amine (p-TTA), bis{4-[bis(4-methylphenyl)amino]phenyl}oligothiophene (BMA-nT), 2,5-bis{4-[bis(4-methylphenyl)amino]phenyl}thiophene (BMA-1T), 5,5″-bis{4-[bis(4-methylphenyl)amino]phenyl}-2,2′-bithiophene (BMA-2T), 5,5″-bis{4-[bis(4-methylphenyl)amino]phenyl}-2,2′:5′,2″-terthiophene (BMA-3T), 5,5′″-bis{4-[bis(4-methylphenyl)amino]phenyl}-2,2′:5′,2″:5″,2″-quaterthiophene (BMA-4T), 2-(4-biphenyl)-5-(4-tert-butylphenyl)-1,3,4-oxadiazole (PBD), 2,9-dimethyl-4,7-diphenyl-1,10-phenanthroline (BCP), 4,7-diphenyl-1,10-phenanthroline (Bphen), 2,9-bis(naphthalen-2-yl)-4,7-diphenyl-1,10-phenanthroline (NBphen), 1,3-bis[2-(4-tert-butylphenyl)-1,3,4-oxadiazo-5-yl]benzene (OXD-7), 3-(4-biphenyl)-4-phenyl-5-tert-butylphenyl-1,2,4-triazole (TAZ), 4,4′-bis(4,6-diphenyl-1,3,5-triazin-2-yl)biphenyl (BTB), 2,5-bis(1-naphthyl)-1,3,4-oxadiazole (BND), 4,4′-bis(carbazol-9-yl)biphenyl (CBP), 2,2′,7,7′-tetrakis(carbazol-9-yl)-9,9-spirobifluorene (Spiro-CBP), 1,3,5-tris(carbazol-9-yl)benzene (TCP), 1,3-bis(carbazol-9-yl)benzene (MCP), 4,4′-di(triphenylsilyl)-biphenyl (BSB), 1,4-bis(triphenylsilyl)benzene (UGH-2), and 1,3-bis(triphenylsilyl)benzene (UGH-3); and inorganic fluorescent bodies composed of quantum dots of ZnO, CdSe, ZnSe, MN, GaN, InN, InP, GaP, GaAs, ZnS, CdS, and the like.

### Fourth Embodiment

This embodiment is different from the first embodiment in that the first fluorescent body, the second fluorescent body, the third fluorescent body, the fourth fluorescent body, and the fifth fluorescent body are used as outside light-absorbing optical functional materials and an eighth fluorescent body is used as a light-guiding optical functional material.

The eighth fluorescent body is a fluorescent body having a chemical structure represented by the chemical structural formula (i) or the chemical structural formula (ii). By changing a substituent X in the chemical structural formula (i) or a substituent R in the chemical structural formula (ii), the peak wavelength of the absorption spectrum of the eighth fluorescent body is controlled to be about 700 nm and the peak wavelength of the emission spectrum is controlled to be about 800 nm. The eighth fluorescent body has a fluorescence quantum yield of 90%.

The mixing ratios (the volume ratios relative to a PMMA resin included in the light guide body) of the first fluorescent body, the second fluorescent body, the third fluorescent body, the fourth fluorescent body, and the fifth fluorescent body serving as the outside light-absorbing optical functional materials are each 0.02%. The mixing ratio of the eighth fluorescent body serving as the light-guiding optical functional material is 5% relative to the outside light-absorbing optical functional materials, that is, 0.001%. Also in this embodiment, cascaded energy transfer occurs in the order of the first fluorescent body, the second fluorescent body, the third fluorescent body, the fourth fluorescent body, the fifth fluorescent body, and the eighth fluorescent body, and substantially only the eighth fluorescent body emits light.

In this embodiment, sunlight with a wavelength of up to 700 nm can be absorbed. Fifty percent of a spectrum of sunlight that has entered the light guide body is absorbed by the first fluorescent body, the second fluorescent body, the third fluorescent body, the fourth fluorescent body, and the fifth fluorescent body. The excitation energy is transferred to the eighth fluorescent body without being wasted. The fluorescence quantum yield of the eighth fluorescent body is 90%. Therefore, the excitation energy transferred to the eighth fluorescent body is converted into light in the eighth fluorescent body at a high fluorescence quantum yield of 90%. The light emitted from the eighth fluorescent body propagates uniformly in all directions. Herein, since the output loss due to the difference in refractive index between the light guide body and the air layers (the ratio of light emitted from the first principal surface and second principal surface of the light guide body) is 25% and the loss generated during reflection at the reflective layer disposed on the second principal surface is about 4%, the energy that reaches a solar cell element is about 32% of the sunlight that has entered the light guide body. This energy of 32% can be used for power generation of the solar cell element because almost no self-absorption is caused during light guiding.

In this embodiment, the emission wavelength of the light-guiding optical functional material is 800 nm. The light with a wavelength of 800 nm that leaks out through the light-entering surface of the light guide body during light guiding has a wavelength longer than wavelengths of visible light. Consequently, an observer sees the light guide body hardly emitting any light. Furthermore, almost all visible light is absorbed, and thus the light guide body looks like smoked glass. In the examples of the first embodiment and the second embodiment, the light that leaks out through the light-entering surface of the light guide body is red light, and thus the light guide body looks like a red plate. There is no correlation between the function and the color of solar cell modules. However, when such solar cell modules are installed on a roof, a window, a wall, or the like, red is not always a preferred color. On the other hand, the light guide body in this embodiment has a color of smoked glass. Therefore, the solar cell module can be installed in a conspicuous place such as a roof, a window, or a wall without looking out of place. In other words, the solar cell module can be installed in various spaces.

Table 3 shows the conversion efficiency, the amount of power generation, and the cost per watt when the light guide body (fluorescence guide body) of this embodiment and each of the solar cells shown in FIG. 12 are combined with each other. In Table 3, “the case where fluorescence guide body is used” and “the case where fluorescence guide body is not used” have the same meaning as in Table 1.

TABLE 3

| | | Conversion | Amount of | Cost per |
|---|---|---|---|---|
| | Conversion | efficiency | power | watt in |
| | efficiency in | in the case | generation in | the case |
| | the case where | where | the case where | where |
| | fluorescence | fluorescence | fluorescence | fluorescence |
| Type of | guide body is | guide body | guide body is | guide body |
| solar cell | not used | is used | used | is used |
| Crystalline | 15% | 25% | 48 W/m² | 100 yen/W |
| Si | | | | |
| α-Si | 8.5% | 0% | 0 W/m² | — |
| CdTe | 9% | 20% | 64 W/m² | 80 yen/W |
| GaAs | 24% | 52% | 160 W/m² | 115 yen/W |
| (monolayer) | | | | |

As shown in Table 3, also in this embodiment, the conversion efficiency in the case where the fluorescence guide body is used is higher than that in the case where the fluorescence guide body is not used. Furthermore, since the loss due to self-absorption during light guiding is small, high power generation efficiency is achieved and the cost per watt is decreased.

In this embodiment, a maximum efficiency of 52% in a GaAs monolayer solar cell can be used. Since 32% of light can be concentrated at the first end surface of the fluorescence guide body, a highly efficient solar cell module having a power output of 160 W/m² and a very low cost per watt is provided at low cost. On the other hand, an α-Si solar cell has a spectral sensitivity of 0 and thus does not function as a solar cell. Therefore, for the purpose of efficiently performing power generation, it is important to appropriately combine the spectrum of fluorescence made to enter the solar cell element and the spectral sensitivity of the solar cell element.

### Fifth Embodiment

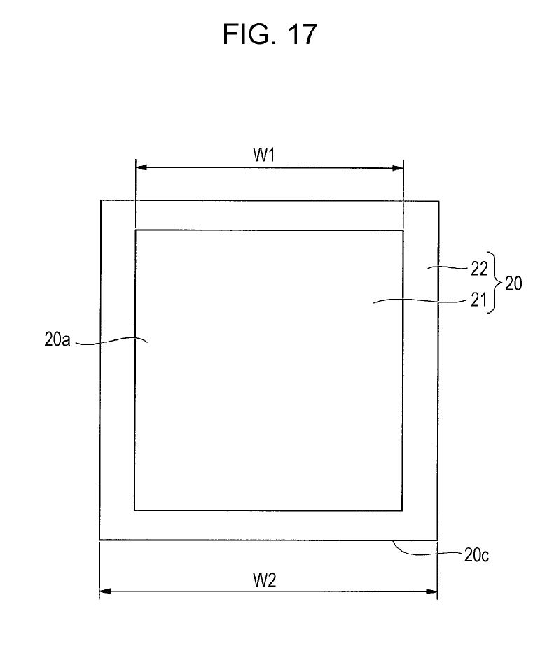

FIG. 17 is a plan view showing a light guide body 20 that is applied to a solar cell module according to a fifth embodiment, the light guide body 20 being viewed in a direction of the normal to the light-entering surface.

This embodiment is different from the first embodiment in that at least one of the types and the mixing ratios of outside light-absorbing optical functional materials contained is different between a portion close to a light-emitting surface (first end surface 20c) of the light guide body 20 and a portion farther from the light-emitting surface.

In this embodiment, a first light guide portion 21 located in the center of the light guide body 20 contains the above-described first fluorescent body, second fluorescent body, third fluorescent body, and fourth fluorescent body. A second light guide portion 22 located in the periphery of the light guide body 20 contains the third fluorescent body and the fourth fluorescent body. The mixing ratios (the volume ratios relative to a PMMA resin included in the light guide body 20) of the first fluorescent body, the second fluorescent body, the third fluorescent body, and the fourth fluorescent body mixed in the first light guide portion 21 of the light guide body are 0.1%, 0.5%, 0.1%, and 0.005%, respectively. The mixing ratios of the third fluorescent body and the fourth fluorescent body mixed in the second light guide portion 22 of the light guide body 20 are 0.1% and 0.005%, respectively. The light guide body 20 is, for example, a fifty-centimeter-square light guide body composed of a PMMA resin. A forty-five-centimeter-square region in the center is the first light guide portion 21 and a frame-shaped region having a width of 5 cm and surrounding the forty-five-centimeter-square region is the second light guide portion 22.

In this embodiment, the balance of energy transfer is intentionally disturbed in the first light guide portion 21 so that a large amount of green light is emitted from the first light guide body 21. Therefore, all the light that propagates through the first light guide portion 21 is not an emission color of the fourth fluorescent body. The light emitted from the second fluorescent body mixed in a large amount is also emitted from the first light guide portion 21.

In this case, the light output from the first light guide portion 21 is light having a mixed color of emission colors of the fourth fluorescent body and the second fluorescent body, that is, orange light. If the light emitted from the second fluorescent body directly enters the solar cell element through the first end surface 20c of the light guide body 20, highly efficient power generation cannot be achieved. For example, in GaAs solar cells, a conversion efficiency of 32% is achieved in the emission spectrum of the fourth fluorescent body whereas a conversion efficiency of only about 22% is achieved in the emission spectrum of the second fluorescent body. By surrounding the first light guide portion 21 with the second light guide portion 22 containing only the third fluorescent body and fourth fluorescent body as in this embodiment, the light emitted from the second fluorescent body can be converted into light that undergoes photoelectric conversion at a high conversion efficiency in the solar cell element, and the converted light is emitted.

In this embodiment, the first light guide portion 21 functions as a light guide portion in which part of outside light that has entered the first light guide portion 21 through the light-emitting surface is absorbed by the first fluorescent body, the second fluorescent body, the third fluorescent body, and the fourth fluorescent body and the light emitted from the second fluorescent body and the fourth fluorescent body propagates toward the light-emitting surface 20c. The second light guide portion 22 functions as a converting portion in which the light that has entered the second light guide portion 22 from the first light guide portion 21 is converted into light (light emitted from the fourth fluorescent body) having higher spectral sensitivity in a solar cell element (not shown) disposed on the light-emitting surface 20c than the light that has entered the second light guide portion 22 and is made to enter the solar cell element. The light that is emitted from the second fluorescent body and enters the second light guide portion 22 from the first light guide portion 21 is absorbed by the third fluorescent body in the second light guide portion 22, and the excitation energy is transferred to the fourth fluorescent body in the second light guide portion 22 through the Förster mechanism. Consequently, the light emitted from the second light guide body 22 (i.e., light emitted from the light-emitting surface of the light guide body 20) is substantially only light emitted from the fourth fluorescent body. Therefore, by using the solar cells shown in FIG. 12 as the solar cell element disposed on the light-emitting surface 20c, highly efficient power generation can be achieved in the solar cell element.

For example, the amount of power generation in the case where the light guide body 20 and a GaAs solar cell are combined is calculated to be about 16 W whereas the amount of power generation in the case where only the first light guide portion 21 constitutes the entire light guide body without disposing the second light guide portion 22 is calculated to be about 14 W. Thus, it is clear that a large amount of power generation is achieved by disposing the second light guide portion 22 between the first light guide portion 21 and the solar cell element.

When the mixing ratio of the second fluorescent body in the first light guide portion 21 is decreased and the types and mixing ratios of the optical functional materials mixed in the first light guide portion 21 and the second light guide portion 22 are the same as in the first embodiment, the amount of power generation is 17.5 W, which is about 10% higher than the amount of power generation in this embodiment. The reason for this is as follows. The light that is emitted from the second fluorescent body and enters the second light guide portion 22 from the first light guide portion 21 is absorbed by the third fluorescent body in the second light guide portion 22 through the processes of light emission and absorption, which generates an energy loss of about 8%. Furthermore, the first fluorescent body and the second fluorescent body are not mixed into the second light guide portion 22, which decreases the amount of sunlight absorbed and generates an energy loss of about 2%.

However, when the types and mixing ratios of the optical functional materials mixed in the first light guide portion 21 are adjusted so that the spectrum of light emitted from the light-emitting surface 20c of the light guide body 20 is different from the spectrum of light emitted from the light-entering surface 20a of the light guide body 20 as in this embodiment, the color of the appearance of the light guide body 20 can be adjusted to a desired color. Therefore, a solar cell module with good design can be provided. In this embodiment, the mixing ratio of the second fluorescent body mixed in the first light guide portion 21 is intentionally increased to change the color of the appearance of the light guide body 20. However, the resulting decrease in conversion efficiency is suppressed by performing color conversion in the second light guide portion 22. Therefore, a solar cell module having both good design and high power generation efficiency can be provided.

In this embodiment, the light emitted from the second fluorescent body is caused to leak out from the light-entering surface 20a by intentionally changing the mixing ratios of a plurality of fluorescent bodies. However, even when the mixing ratios of a plurality of fluorescent bodies are not intentionally changed, there are combinations with which 100% of energy transfer does not always occur between the plurality of fluorescent bodies depending on the emission characteristics and absorption characteristics of the plurality of fluorescent bodies. Even in such a case, by disposing a converting portion that can adjust the color of light in the periphery of the light guide body 20 as in this embodiment, single-wavelength light (light emitted from an optical functional material having the longest peak wavelength of an emission spectrum) having high conversion efficiency can be made to enter the solar cell element disposed on the light-emitting surface 20c of the light guide body 20.

### Sixth Embodiment

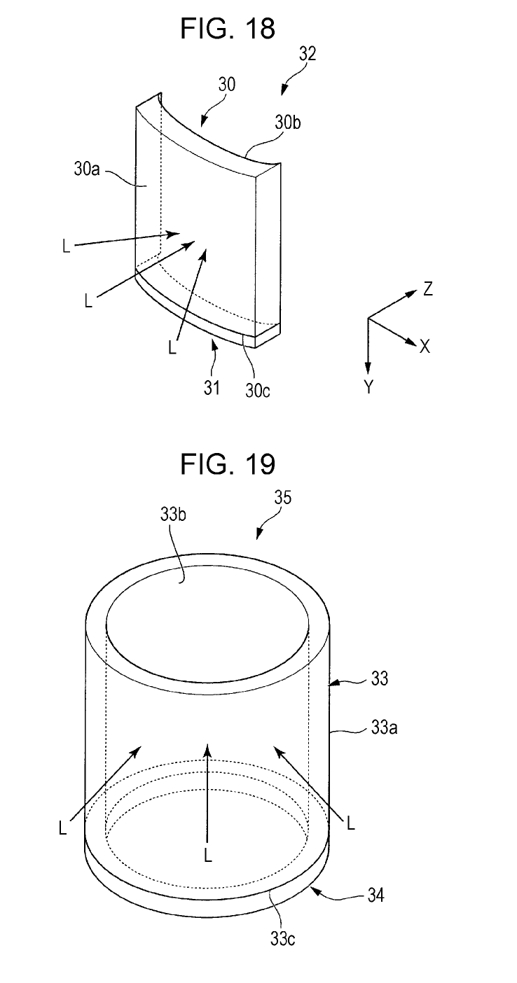

FIG. 18 is a schematic view showing a solar cell module 32 according to a sixth embodiment. The solar cell module 32 is different from the solar cell module 1 according to the first embodiment in terms of the shapes and arrangement of a light guide body 30 and a solar cell element 31. Herein, only the shapes and arrangement of the light guide body 30 and the solar cell element 31 will be described, and the detailed description of other elements is omitted.

In the solar cell module 32, the light guide body 30 is a plate-shaped curved member and the solar cell element 31 is configured to receive light that is emitted from a curved first end surface 30c serving as a light-emitting surface of the light guide body 30. The light guide body 30 has, for example, a shape in which a plate-shaped member having a uniform thickness is curved about an axis parallel to the Y axis. The light guide body 30 includes a first principal surface 30a curved so as to protrude outward and a second principal surface 30b, and the first principal surface 30a is a light-entering surface which outside light (e.g., sunlight) L enters.

The light L that has entered the light-entering surface 30a is absorbed by a plurality of optical functional materials (not shown) dispersed in the light guide body 30. Then, energy transfer due to the Förster mechanism occurs between the plurality of optical functional materials, and light emitted from an optical functional material having the longest peak wavelength of an emission spectrum is concentrated at the light-emitting surface 30c whose area is smaller than that of the light-entering surface 30a and emitted from the light-emitting surface 30c. Examples of the plurality of optical functional materials dispersed in the light guide body 30 include the first fluorescent body 8a, the second fluorescent body 8b, the third fluorescent body 8c, and the fourth fluorescent body 8d shown in FIGS. 2 to 8.

For example, a GaAs solar cell is used as the solar cell element 31. The solar cell element 31 is disposed so that the light-receiving surface of the solar cell element 31 faces the first end surface 30c of the light guide body 30. As a result of comparison of spectral sensitivities of the solar cell element 31 at the peak wavelengths of emission spectra of the first fluorescent body 8a, the second fluorescent body 8b, the third fluorescent body 8c, and the fourth fluorescent body 8d, the spectral sensitivity of the solar cell element 31 at the peak wavelength of an emission spectrum of an optical functional material (fourth fluorescent body 8d) having the longest peak wavelength of an emission spectrum among the plurality of optical functional materials (first fluorescent body 8a, second fluorescent body 8b, third fluorescent body 8c, and fourth fluorescent body 8d) is higher than the spectral sensitivities of the solar cell element 31 at the peak wavelengths of emission spectra of any other optical functional materials (first fluorescent body 8a, second fluorescent body 8b, and third fluorescent body 8c) contained in the light guide body 30. Thus, a solar cell module 32 with high power generation efficiency is provided.

In the solar cell module 32, the light-entering surface 30a of the light guide body 30 is a curved surface. Therefore, even if the incident angle of light L changes in a curved direction of the light guide body 30 with time periods such as daytime and evening, the amount of power generation does not significantly vary. In general, in power generation with solar cells, the angle of a solar cell is controlled in two axial directions by disposing a sun tracker so that the light-receiving surface of the solar cell faces in an incident direction of light. However, when the light-entering surface 30a of the light guide body 30 has a curved shape so as to face in various directions as in this embodiment, there is no need of disposing such a sun tracker. Even if such a sun tracker is disposed, only the angle in a direction orthogonal to the curved direction may be controlled and thus the sun tracker can be simplified compared with the case where the angle is controlled in two axial directions. In this embodiment, the light guide body 30 has a shape curved in one direction, but the shape of the light guide body 30 is not limited thereto. For example, a domical shape such as a hemispherical shape or a bell-like shape can be employed. In this case, the sun tracker is not required.

Since the solar cell module 32 includes the light guide body 30 with a curved shape, the light guide body 30 can be installed on a curved wall or a curved roof of buildings. In this embodiment, the light guide body 30 has a shape curved in one direction. However, the shape of the light guide body 30 is not limited to such a simple shape. Any shape such as a shape of a roofing tile or a wave-like shape can be designed.

With the place where the light guide body 30 is installed, the light guide body 30 may have not only the curved shape but also a bent shape with a ridgeline. The curved surface or the bent surface may be formed in at least part of the light-entering surface. Thus, the above-described effects are provided.

### Seventh Embodiment

FIG. 19 is a schematic view showing a solar cell module 35 according to a seventh embodiment. The solar cell module 35 is different from the solar cell module 1 according to the first embodiment in terms of the shapes and arrangement of a light guide body 33 and a solar cell element 34. Herein, only the shapes and arrangement of the light guide body 33 and the solar cell element 34 will be described, and the detailed description of other elements is omitted.

In the solar cell module 35, the light guide body 33 is a cylindrical member having a central axis that is parallel to the Y axis and the solar cell element 34 is configured to receive light that is emitted from a first end surface 33c serving as a light-emitting surface of the light guide body 33. The light guide body 33 has, for example, a cylindrical shape with a uniform thickness. The peripheral surface of the light guide body 33 is a first principal surface 33a and the inner circumferential surface of the light guide body 33 is a second principal surface 33b. Of the first principal surface 33a and the second principal surface 33b of the light guide body 33, the first principal surface 33a curved so as to protrude outward is a light-entering surface which outside light (e.g., sunlight) L enters.

The light L that has entered the light-entering surface 33a is absorbed by a plurality of optical functional materials (not shown) dispersed in the light guide body 33. Then, energy transfer due to the Förster mechanism occurs between the plurality of optical functional materials, and light emitted from an optical functional material having the longest peak wavelength of an emission spectrum is concentrated at the light-emitting surface 33c whose area is smaller than that of the light-entering surface 33a and emitted from the light-emitting surface 33c. Examples of the plurality of optical functional materials dispersed in the light guide body 33 include the first fluorescent body 8a, the second fluorescent body 8b, the third fluorescent body 8c, and the fourth fluorescent body 8d shown in FIGS. 2 to 8.

For example, a GaAs solar cell is used as the solar cell element 34. The solar cell element 34 is disposed so that the light-receiving surface of the solar cell element 34 faces the first end surface 33c of the light guide body 33. As a result of comparison of spectral sensitivities of the solar cell element 34 at the peak wavelengths of emission spectra of the first fluorescent body 8a, the second fluorescent body 8b, the third fluorescent body 8c, and the fourth fluorescent body 8d, the spectral sensitivity of the solar cell element 34 at the peak wavelength of an emission spectrum of an optical functional material (fourth fluorescent body 8d) having the longest peak wavelength of an emission spectrum among the plurality of optical functional materials (first fluorescent body 8a, second fluorescent body 8b, third fluorescent body 8c, and fourth fluorescent body 8d) is higher than the spectral sensitivities of the solar cell element 34 at the peak wavelengths of emission spectra of any other optical functional materials (first fluorescent body 8a, second fluorescent body 8b, and third fluorescent body 8c) contained in the light guide body 33. Thus, a solar cell module 35 with high power generation efficiency is provided.

In the solar cell module 35, the light-entering surface 33a of the light guide body 33 is a curved surface. Therefore, even if the incident angle of light L changes in a curved direction of the light guide body 33 with time periods such as daytime and evening, the amount of power generation does not significantly vary. Since the light guide body 33 has a cylindrical shape, the light guide body 33 can be installed on a pillar of buildings, a utility pole, and the like. In this embodiment, the light guide body 33 has a cylindrical shape. However, the shape of the light guide body 33 is not limited to such a shape. Any shape whose cross section parallel to the XZ plane is, for example, elliptical or polygonal can be designed in accordance with the place where the light guide body 33 is installed.

### Eighth Embodiment

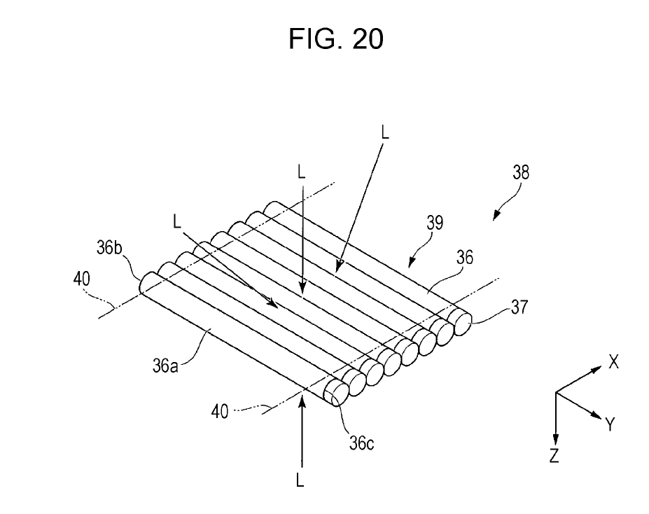

FIG. 20 is a schematic view showing a solar cell module 38 according to an eighth embodiment. The solar cell module 38 is different from the solar cell module 1 according to the first embodiment in terms of the shapes and arrangement of light guide bodies 36 and solar cell elements 37. Herein, only the shapes and arrangement of the light guide bodies 36 and the solar cell elements 37 will be described, and the detailed description of other elements is omitted.

In the solar cell module 38, each of the light guide bodies 36 is a pillar-shaped member that extends in the Y direction and each of the solar cell elements 37 is configured to receive light that is emitted from a first end surface 36c serving as a light-emitting surface of the light guide body 36. The light guide body 36 has, for example, a columnar shape with a central axis that is parallel to the Y axis. The peripheral surface of the light guide body 36 is a first principal surface 36a, which is a light-entering surface which outside light (e.g., sunlight) L enters.

For example, a GaAs solar cell is used as the solar cell element 37. The solar cell element 37 is disposed so that the light-receiving surface of the solar cell element 37 faces the first end surface 36c of the light guide body 36. As a result of comparison of spectral sensitivities of the solar cell element 37 at the peak wavelengths of emission spectra of the first fluorescent body 8a, the second fluorescent body 8b, the third fluorescent body 8c, and the fourth fluorescent body 8d, the spectral sensitivity of the solar cell element 37 at the peak wavelength of an emission spectrum of an optical functional material (fourth fluorescent body 8d) having the longest peak wavelength of an emission spectrum among the plurality of optical functional materials (first fluorescent body 8a, second fluorescent body 8b, third fluorescent body 8c, and fourth fluorescent body 8d) is higher than the spectral sensitivities of the solar cell element 37 at the peak wavelengths of emission spectra of any other optical functional materials (first fluorescent body 8a, second fluorescent body 8b, and third fluorescent body 8c) contained in the light guide body 36. Thus, a solar cell module 38 with high power generation efficiency is provided.

In FIG. 20, eight pairs of unitary units 39 each including a pair of the light guide body 36 and the solar cell element 37 are arranged in the X direction so as to be adjacent to each other. The number of the unitary units 39 is not limited thereto. The number of the unitary units 39 may be one pair or two or more pairs other than eight pairs. When a plurality of the unitary units 39 are disposed, the solar cell module 38 can be installed on a flat surface. When a plurality of the unitary units 39 are flexibly connected to each other using a cord-shaped connecting member 40, the solar cell module 38 can be installed, for example, on a curved surface which is not a flat surface in a variety of shapes. Furthermore, such a solar cell module 38 can be rolled out when necessary and put away by being rolled up when not necessary like a doorway curtain. When a plurality of the unitary units 39 are connected to each other using a hard rod-shaped connecting member 40 so as to be separated from each other, air passes through spaces between the light guide bodies 36. Thus, wind pressure can be reduced, which makes it easy to install a base of the solar cell module.

In this embodiment, the light guide body 36 has a columnar shape. However, the shape of the light guide body 36 is not limited to such a shape. Any shape whose cross section parallel to the XZ plane is, for example, elliptical or polygonal can be designed in accordance with the place where the light guide body 36 is installed.

In the solar cell module 38, the light-entering surface 36a of the light guide body 36 is a curved surface. Therefore, even if the incident angle of light L changes in a curved direction of the light guide body 36 with time periods such as daytime and evening, the amount of power generation does not significantly vary. Furthermore, since the light guide body 36 has a columnar shape, the solar cell module 38 can be installed not only on a flat surface but also on a curved surface by flexibly connecting a plurality of the light guide bodies 36 in parallel. Moreover, the solar cell module 38 can be rolled out/rolled up like a doorway curtain.

### [Solar Photovoltaic Power Generation Device]

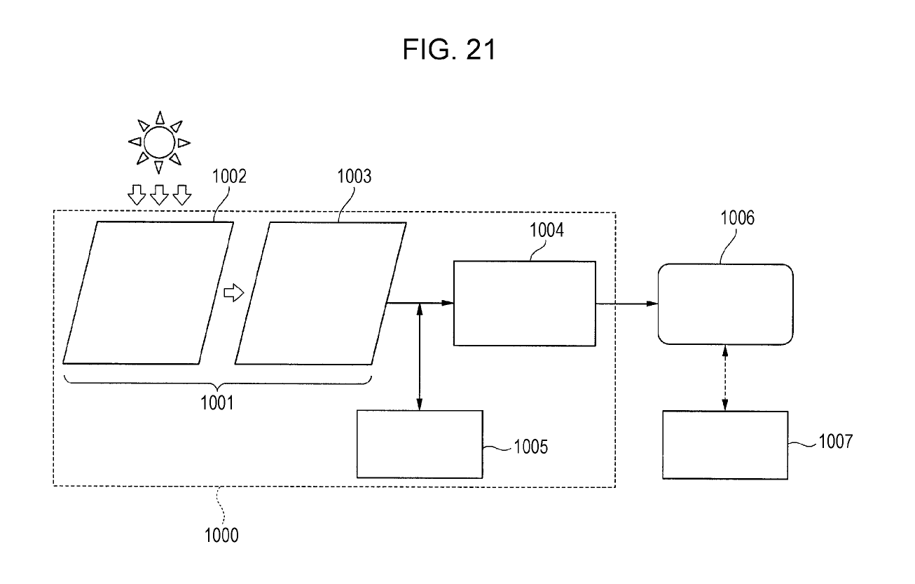

FIG. 21 schematically shows a solar photovoltaic power generation device 1000.

The solar photovoltaic power generation device 1000 includes a solar cell module 1001 that converts sunlight energy into electric power, an inverter (DC/AC converter) 1004 that converts direct-current power output from the solar cell module 1001 into alternating-current power, and a storage battery 1005 that stores the direct-current power output from the solar cell module 1001.

The solar cell module 1001 includes a light guide body 1002 that concentrates sunlight and a solar cell element 1003 that performs power generation using the concentrated sunlight. For example, the solar cell modules described in the first embodiment to the eighth embodiment are used as the solar cell module 1001.

The solar photovoltaic power generation device 1000 supplies electric power to an external electronic apparatus 1006. Electric power is supplied to the electronic apparatus 1006 from an auxiliary power supply 1007, when necessary.

The solar photovoltaic power generation device 1000 includes the solar cell module according to the present invention and therefore serves as a solar photovoltaic power generation device with high power generation efficiency.

### INDUSTRIAL APPLICABILITY

The present invention can be applied to a light guide body, a solar cell module, and a solar photovoltaic power generation device.

### DESCRIPTION OF REFERENCE NUMERALS

1: solar cell module
4: light guide body
4a: light-entering surface
4c: light-emitting surface
6: solar cell element
8a, 8b, 8c, 8d: fluorescent body (optical functional material)
20: light guide body
30: light guide body
30: light-entering surface
30c: light-emitting surface
31: solar cell element
32: solar cell module
33: light guide body
33a: light-entering surface
33c: light-emitting surface
34: solar cell element
35: solar cell module
36: light guide body
36a: light-entering surface
36c: light-emitting surface
37: solar cell element
38: solar cell module
39: unitary unit
40: connecting member
1000: solar photovoltaic power generation device
L, L1: light

1. A light guide body comprising:
a light-entering surface which outside light enters;
one or more outside light-absorbing optical functional materials that absorb part of the outside light which enters the light-entering surface;
a light-guiding optical functional material that is excited by energy of light absorbed by the one or more outside light-absorbing optical functional materials and that emits light different from the light; and
a light-emitting surface whose area is smaller than the light-entering surface and from which the light emitted from the light-guiding optical functional material is emitted,
wherein a mixing ratio of the light-guiding optical functional material is smaller than a mixing ratio of at least an optical functional material having a largest mixing ratio among the one or more outside light-absorbing optical functional materials.

2. The light guide body according to claim 1, wherein the mixing ratio of the light-guiding optical functional material is smaller than a mixing ratio of any of the one or more outside light-absorbing optical functional materials.

3. The light guide body according to claim 1, wherein the mixing ratio of the light-guiding optical functional material is 10% or less of the mixing ratio of the optical functional material having the largest mixing ratio among the one or more outside light-absorbing optical functional materials.

4. The light guide body according to claim 1, wherein the one or more outside light-absorbing optical functional materials include one or more optical functional materials having a fluorescence quantum yield of 80% or less.

5. The light guide body according to claim 4, wherein a fluorescence quantum yield of the light-guiding optical functional material is larger than a fluorescence quantum yield of at least an optical functional material having a smallest fluorescence quantum yield among the one or more outside light-absorbing optical functional materials.

6. The light guide body according to claim 5, wherein the fluorescence quantum yield of the light-guiding optical functional material is larger than a fluorescence quantum yield of any of the one or more outside light-absorbing optical functional materials.

7. The light guide body according to claim 1, wherein at least one of types and mixing ratios of the one or more outside light-absorbing optical functional materials contained is different between a portion close to the light-emitting surface and a portion farther from the light-emitting surface.

8. The light guide body according to claim 7, wherein a spectrum of light emitted from the light-emitting surface is different from a spectrum of light emitted from the light-entering surface.

9. The light guide body according to claim 1, wherein only one optical functional material is used as the outside light-absorbing optical functional materials.

10. The light guide body according to claim 1, wherein a plurality of optical functional materials are used as the outside light-absorbing optical functional materials.

11. The light guide body according to claim 10, wherein all light in a visible region is absorbed by the plurality of outside light-absorbing optical functional materials, and light emitted from the light-guiding optical functional material is infrared light.

12. A solar cell module comprising:
the light guide body according to claim 1; and
a solar cell element that receives light emitted from the light-emitting surface of the light guide body,
wherein a spectral sensitivity of the solar cell element at a peak wavelength of an emission spectrum of the light-guiding optical functional material included in the light guide body is larger than a spectral sensitivity of the solar cell element at a peak wavelength of an emission spectrum of any of the one or more outside light-absorbing optical functional materials included in the light guide body.

13. The solar cell module according to claim 12, wherein the light-entering surface of the light guide body is a flat surface.

14. The solar cell module according to claim 13,
wherein the light guide body is a plate-shaped flat member, and
the solar cell element receives the light which is emitted from an end surface of the light guide body, the end surface serving as the light-emitting surface.

15. The solar cell module according to claim 12, wherein at least part of the light-entering surface of the light guide body is a bent surface or a curved surface.

16. The solar cell module according to claim 15,
wherein the light guide body is a plate-shaped curved member, and
the solar cell element receives the light which is emitted from a curved end surface of the light guide body, the curved end surface serving as the light-emitting surface.

17. The solar cell module according to claim 15,
wherein the light guide body is a cylindrical member, and
the solar cell element receives the light which is emitted from an end surface of the light guide body, the end surface serving as the light-emitting surface.

18. The solar cell module according to claim 15,
wherein the light guide body is a pillar-shaped member, and
the solar cell element receives the light which is emitted from an end surface of the light guide body, the end surface serving as the light-emitting surface.

19. The solar cell module according to claim 18, wherein a plurality of unitary units each including a pair of the light guide body and the solar cell element are arranged so as to be adjacent to each other, and the plurality of unitary units are flexibly connected to each other using a cord-shaped connecting member.

20. The solar cell module according to claim 18, wherein a plurality of unitary units each including a pair of the light guide body and the solar cell element are arranged so as to be adjacent to each other, and the plurality of unitary units are connected to each other so as to be separated from each other.

21. A solar photovoltaic power generation device comprising the solar cell module according to claim 12.
